(19) United States
(12) Patent Application Publication
(10) Pub. No.: US 2025/0048885 A1
(43) Pub. Date: Feb. 6, 2025

(54) DISPLAY DEVICE, MANUFACTURING METHOD OF DISPLAY DEVICE, AND OPTICAL DEVICE

(71) Applicant: Samsung Display Co., Ltd., Yongin-Si (KR)

(72) Inventors: Kyung Bae KIM, Yongin-si (KR); Do Yeong PARK, Yongin-si (KR); Yong Hee LEE, Yongin-si (KR); Ji Hye LEE, Yongin-si (KR)

(21) Appl. No.: 18/740,507

(22) Filed: Jun. 12, 2024

(30) Foreign Application Priority Data
Jul. 31, 2023 (KR) 10-2023-0100047

(51) Int. Cl. H10K 59/80; G02B 27/01; H10K 59/122; H10K 59/131; H10K 59/38; H10K 71/60

(52) U.S. Cl. CPC H10K 59/80518; G02B 27/0172; H10K 59/122; H10K 59/131; H10K 59/38; H10K 71/60; G02B 2027/0178

(57) ABSTRACT

The present disclosure relates to a display device, and more particularly, to a display device capable of making resonance distances different from each other according to a wavelength of light to be emitted from each pixel while simplifying process steps, a manufacturing method of the display device, and an optical device including the display device. A display device comprises: a substrate; a bank disposed on the substrate and defining a plurality of emission areas; a plurality of pixel electrodes disposed in the plurality of emission areas; and at least one stepped electrode disposed between a pixel electrode of at least one emission area and the substrate. In the respective emission areas, the numbers of stepped electrodes between the respective pixel electrodes and the substrate are different from each other.

### CROSS-REFERENCE TO RELATED APPLICATION

This application claims priority from Korean Patent Application No. 10-2023-0100047 filed on Jul. 31, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device, and more particularly, to a display device capable of making resonance distances different from each other according to a wavelength of light to be emitted from each pixel while simplifying process steps, a manufacturing method of the display device, and an optical device including the display device.

### 2. Description of the Related Art

An organic light emitting display apparatus includes display elements whose luminance is changed by a current, for example, organic light emitting diodes.

### SUMMARY

Aspects of the present disclosure provide a display device capable of making resonance distances different from each other according to a wavelength of light to be emitted from each pixel while simplifying process steps, a manufacturing method of the display device, and an optical device including the display device.

According to an embodiment of the disclosure, a display device comprises: a substrate; a bank disposed on the substrate and defining a plurality of emission areas; a plurality of pixel electrodes disposed in the plurality of emission areas; and at least one stepped electrode disposed between a pixel electrode of at least one emission area and the substrate. In the respective emission areas, the numbers of stepped electrodes between the respective pixel electrodes and the substrate are different from each other.

In an embodiment, the numbers of stepped electrodes are the numbers of stepped electrodes stacked on different layers with an insulating film interposed therebetween in the respective emission areas.

In an embodiment, the plurality of emission areas provide light of different colors.

In an embodiment, the display device further comprises a power line connected to the at least one stepped electrode.

In an embodiment, the at least one stepped electrode is a floating electrode.

In an embodiment, the display device further comprises a pixel connection electrode connected to the pixel electrode of the at least one emission area.

In an embodiment, the at least one stepped electrode is connected to the pixel connection electrode.

In an embodiment, the display device further comprises a plurality of color filters disposed to correspond to the plurality of emission areas and providing light of different colors.

In an embodiment, each of the plurality of pixel electrodes includes: a reflective electrode disposed on the substrate; and a light-transmitting electrode disposed on the reflective electrode and connected to the reflective electrode through a contact hole of an insulating film.

In an embodiment, the at least one stepped electrode is disposed between the reflective electrode of the at least one emission area and the substrate.

In an embodiment, in the respective emission areas, the numbers of stepped electrodes between the respective reflective electrodes and the substrate are different from each other.

In an embodiment, in the respective emission areas, thicknesses of the respective light-transmitting electrodes are different from each other.

In an embodiment, the display device further comprises: a common electrode disposed on a plurality of reflective electrodes of the plurality of pixel electrodes; and a light providing layer disposed between a plurality of light-transmitting electrodes of the plurality of pixel electrodes and the common electrode.

In an embodiment, in the plurality of emission areas, distances between the plurality of reflective electrodes and the common electrode are different from each other.

In an embodiment, a plurality of stepped electrodes include: a first stepped electrode disposed between the substrate and the reflective electrode; a second stepped electrode disposed between the first stepped electrode and the reflective electrode.

In an embodiment, the display device further comprises: a first pixel connection electrode disposed on the same layer as the first stepped electrode, on the substrate; and a second pixel connection electrode disposed on the first pixel connection electrode so as to be disposed on the same layer as the second stepped electrode and connected to the first pixel connection electrode and the reflective electrode through contact holes of an insulating film.

In an embodiment, the first stepped electrode is connected to the first pixel connection electrode.

In an embodiment, the first stepped electrode is formed integrally with the first pixel connection electrode.

In an embodiment, the second stepped electrode is connected to the second pixel connection electrode.

In an embodiment, the second stepped electrode is formed integrally with the second pixel connection electrode.

In an embodiment, the second stepped electrode is connected to the first stepped electrode through a contact hole of an insulating film.

In an embodiment, the first stepped electrode is connected to another first stepped electrode disposed in another emission area.

According to an embodiment of the disclosure, a display device comprises: a substrate; a bank disposed on the substrate and defining a plurality of emission areas; a plurality of pixel electrodes disposed in the plurality of emission areas; and at least one stepped electrode overlapping a pixel electrode of at least one emission area. The numbers of stepped electrodes in the respective emission areas are different from each other.

In an embodiment, the numbers of stepped electrodes are the numbers of stepped electrodes stacked on different layers with an insulating film interposed therebetween in the respective emission areas.

In an embodiment, the plurality of emission areas provide light of different colors.

In an embodiment, the display device further comprises a power line connected to the at least one stepped electrode.

In an embodiment, the at least one stepped electrode is a floating electrode.

In an embodiment, the display device further comprises a pixel connection electrode connected to the pixel electrode of the at least one emission area.

In an embodiment, the at least one stepped electrode is connected to the pixel connection electrode.

According to an embodiment of the disclosure, a manufacturing method of a display device comprises: preparing a substrate; forming stepped electrodes in different numbers in a plurality of emission areas on the substrate; forming a first insulating film on the stepped electrodes; and forming a plurality of pixel electrodes on the first insulating film so as to overlap at least one of the stepped electrodes.

In an embodiment, the numbers of stepped electrodes are the numbers of stepped electrodes stacked on different layers with an insulating film interposed therebetween in the respective emission areas.

In an embodiment, the plurality of emission areas provide light of different colors.

In an embodiment, the forming of the plurality of pixel electrodes includes: forming a plurality of reflective electrodes on the first insulating film so as to overlap at least one of the stepped electrodes; forming a second insulating film on the plurality of reflective electrodes; forming a plurality of contact holes in the second insulating film; forming a plurality of light-transmitting material layers on the second insulating film so as to overlap the plurality of reflective electrodes and be respectively connected to the plurality of reflective electrodes; planarizing the light-transmitting material layers; and forming a plurality of light-transmitting electrodes respectively connected to the plurality of reflective electrodes by patterning the light-transmitting material layers.

In an embodiment, the planarizing of the light-transmitting material layers is performed by chemical mechanical polishing.

In an embodiment, the manufacturing method further comprises forming a plurality of pixel connection electrodes respectively connected to the plurality of pixel electrodes and disposed on different layers from the pixel electrodes with insulating films interposed between the pixel electrodes and the pixel connection electrodes.

In an embodiment, a stepped electrode and a pixel connection electrode disposed on the same layer among the stepped electrodes and the plurality of pixel connection electrodes are connected to each other.

According to an embodiment of the disclosure, an optical device comprises: a display device; and an optical path changing member disposed on the display device. The display device includes: a substrate; a bank disposed on the substrate and defining a plurality of emission areas; a plurality of pixel electrodes disposed in the plurality of emission areas; and at least one stepped electrode disposed between a pixel electrode of at least one emission area and the substrate, and in the respective emission areas. The numbers of stepped electrodes between the respective pixel electrodes and the substrate are different from each other.

With a display device, a manufacturing method of the display device, and an optical device including the display device according to the present disclosure, by stacking stepped electrodes made of the same material as a pixel connection electrode in different numbers for each pixel, resonance distances for each pixel may be adjusted to be different from each other. Accordingly, it is possible to increase and/or optimize a micro-cavity (or thin film resonance) effect on light according to a wavelength of light to be emitted from each pixel and a resonance distance, a resonance order, and the like, corresponding to the wavelength while simplifying process steps.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail exemplary embodiments thereof with reference to the attached drawings.

FIG. 1 is a schematic plan view of an electronic device according to an exemplary embodiment.

FIG. 2 is a perspective view illustrating a display device included in the electronic device according to an exemplary embodiment.

FIG. 3 is a cross-sectional view of the display device of FIG. 2 viewed from the side.

FIG. 4 is a plan view illustrating a display layer of the display device according to an exemplary embodiment.

FIG. 5 is a plan view illustrating the display layer of the display device according to an exemplary embodiment.

FIG. 6 is a plan view of first stepped electrodes, second stepped electrodes, and pixel electrodes disposed in a display area of the display device according to an exemplary embodiment.

FIG. 7 is a plan view of the first stepped electrodes of FIG. 6.

FIG. 8 is a plan view of the second stepped electrodes of FIG. 6.

FIG. 9 is a plan view of the pixel electrodes of FIG. 6.

FIG. 10 is a cross-sectional view of the display device according to an exemplary embodiment taken along line I-I′ of FIG. 6.

FIG. 11 is a cross-sectional view of a display device according to an exemplary embodiment taken along line I-I′ of FIG. 6.

FIG. 12 is a cross-sectional view of a display device according to an exemplary embodiment taken along line I-I′ of FIG. 6.

FIG. 13 is a cross-sectional view of a display device according to an exemplary embodiment taken along line I-I′ of FIG. 6.

FIG. 14 is a cross-sectional view of a display device according to an exemplary embodiment taken along line I-I′ of FIG. 6.

FIG. 15 is a cross-sectional view of a display device according to an exemplary embodiment taken along line I-I′ of FIG. 6.

FIG. 16 is a plan view of a first-first stepped electrode, a first pixel connection electrode, and a first-second stepped electrode of FIG. 15.

FIG. 17 is a cross-sectional view of a display device according to an exemplary embodiment taken along line I-I′ of FIG. 6.

FIG. 18 is a cross-sectional view of a display device according to an exemplary embodiment taken along line I-I′ of FIG. 6.

FIG. 19 is a cross-sectional view of a display device according to an exemplary embodiment taken along line I-I′ of FIG. 6.

FIG. 20 is a cross-sectional view of a display device according to an exemplary embodiment taken along line I-I′ of FIG. 6.

FIG. 21 is a cross-sectional view illustrating a structure of a display element according to an exemplary embodiment.

FIGS. 22, 23, 24, and 25 are cross-sectional views illustrating a structure of a light emitting element according to an exemplary embodiment.

FIG. 26 is a cross-sectional view illustrating an example of an organic light emitting diode of FIG. 24.

FIG. 27 is a cross-sectional view illustrating an example of an organic light emitting diode of FIG. 25.

FIGS. 28, 29, 30, 31, 32, 33, 34, 35, and 36 are cross-sectional views for describing processes of a manufacturing method of the display device according to an exemplary embodiment.

FIG. 37 is an exploded perspective view illustrating a display device according to an exemplary embodiment.

FIG. 38 is a layout diagram illustrating an example of a display panel illustrated in FIG. 37.

FIG. 39 is a block diagram illustrating the display device according to an exemplary embodiment.

FIG. 40 is an equivalent circuit diagram of a first pixel according to an exemplary embodiment.

FIG. 41 is a layout diagram illustrating pixels of a display area according to an exemplary embodiment.

FIG. 42 is a cross-sectional view illustrating an example of a display device taken along line A-A′ of FIG. 41.

FIG. 43 is a perspective view illustrating a head mounted display device according to an exemplary embodiment.

FIG. 44 is an exploded perspective view illustrating an example of the head mounted display device of FIG. 43.

FIG. 45 is a perspective view illustrating a head mounted display device according to an exemplary embodiment.

### DETAILED DESCRIPTION OF THE EMBODIMENTS

The inventive concept will now be described more fully hereinafter with reference to the accompanying drawings, in which embodiments are shown. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, specific exemplary embodiments will be described with reference to the accompanying drawings.

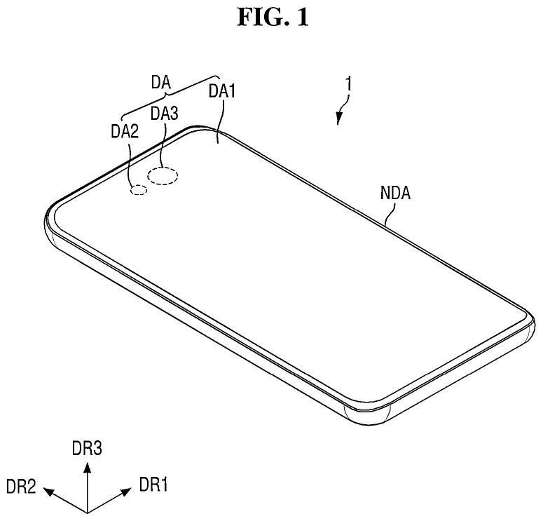

FIG. 1 is a schematic plan view of an electronic device 1 according to an exemplary embodiment.

Referring to FIG. 1, the electronic device 1 displays a moving image or a still image. The electronic device 1 may refer to all electronic devices that provide display screens. For example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, which provide display screens, may be included in the electronic device 1.

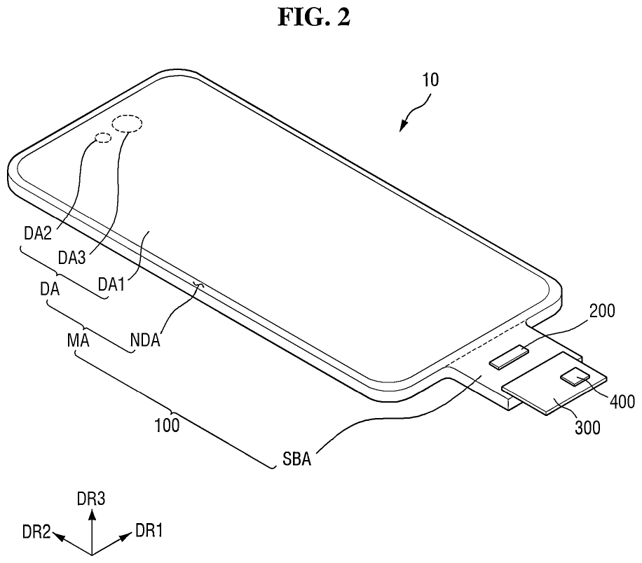

The electronic device 1 may include a display device 10 (see FIG. 2) providing a display screen. Examples of the display device 10 may include an inorganic light emitting diode display device, an organic light emitting display device, a quantum dot light emitting display device, a plasma display device, a field emission display device, and the like. Hereinafter, a case where an organic light emitting diode display device is applied as an example of the display device 10 will be described by way of example, but the present disclosure is not limited thereto, and the same technical spirit may be applied to other display devices if applicable.

A shape of the electronic device 1 may be variously modified. For example, the electronic device 1 may have a shape such as a rectangular shape with a width greater than a length, a rectangular shape with a length greater than a width, a square shape, a quadrangular shape with rounded corners (vertices), other polygonal shapes, or a circular shape. A shape of a display area DA of the electronic device 1 may also be similar to an overall shape of the electronic device 1. In FIG. 1, the electronic device 1 having a rectangular shape with a great length in a second direction DR2 has been illustrated.

The electronic device 1 may include the display area DA and a non-display area NDA. The display area DA is an area in which a screen may be displayed, and the non-display area NDA is an area in which the screen is not displayed. The display area DA may also be referred to as an active area, and the non-display area NDA may also be referred to as a non-active area. The display area DA may occupy substantially the center of the electronic device 1.

The display area DA may include a first display area DA1, a second display area DA2, and a third display area DA3. The second display area DA2 and the third display area DA3 may be areas in which components for adding various functions to the electronic device 1 are disposed, and may correspond to component areas.

FIG. 2 is a perspective view illustrating the display device 10 included in the electronic device 1 according to an exemplary embodiment.

Referring to FIGS. 1 and 2, the electronic device 1 according to an exemplary embodiment may include the display device 10. The display device 10 may provide a screen displayed by the electronic device 1. The display device 10 may have a shape similar to that of the electronic device 1 in plan view. For example, the display device 10 may have a shape similar to a rectangular shape having short sides in a first direction DR1 and long sides in the second direction DR2. A corner where the short side in the first direction DR1 and the long side in the second direction DR2 meet may be rounded with a curvature, but is not limited thereto, and may also be right-angled. The shape of the display device 10 in plan view is not limited to a quadrangular shape, and may be a shape similar to other polygonal shapes, a circular shape, or an elliptical shape.

The display device 10 may include a display panel 100, a display driver 200, a circuit board 300, and a touch driver 400.

The display panel 100 may include a main area MA and a sub-area SBA.

The main area MA may include a display area DA including pixels displaying an image and a non-display area NDA disposed around the display area DA. The display area DA may include a first display area DA1, a second display area DA2, and a third display area DA3. The display area DA may emit light from a plurality of emission areas or a plurality of opening areas. For example, the display panel 100 may include pixel circuits including switching elements, a pixel defining film defining the emission areas or the opening areas, and self-light emitting elements.

For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto.

The non-display area NDA may be an area outside the display area DA. The non-display area NDA may be defined as an edge area of the main area MA of the display panel 100. The non-display area NDA may include a gate driver (not illustrated) supplying gate signals to gate lines, and fan-out lines (not illustrated) connecting the display driver 200 and the display area DA to each other.

The sub-area SBA may be an area extending from one side of the main area MA. The sub-area SBA may include a flexible material that may be bent, folded, and rolled. For example, when the sub-area SBA is bent, the sub-area SBA may overlap the main area MA in a thickness direction (third direction DR3). The sub-area SBA may include the display driver 200 and pad parts connected to the circuit board 300. In an exemplary embodiment, the sub-area SBA may be omitted, and the display driver 200 and the pad parts may be disposed in the non-display area NDA.

The display driver 200 may output signals and voltages for driving the display panel 100. The display driver 200 may supply data voltages to data lines. The display driver 200 may supply source voltages to power lines and supply gate control signals to the gate driver. The display driver 200 may be formed as an integrated circuit (IC) and mounted on the display panel 100 in a chip on glass (COG) manner, a chip on plastic (COP) manner, or an ultrasonic bonding manner. As an example, the display driver 200 may be disposed in the sub-area SBA, and may overlap the main area MA in the thickness direction by bending of the sub-area SBA. As another example, the display driver 200 may be mounted on the circuit board 300.

The circuit board 300 may be attached onto the pad parts of the display panel 100 using an anisotropic conductive film (ACF). Lead lines of the circuit board 300 may be electrically connected to the pad parts of the display panel 100. The circuit board 300 may be a flexible printed circuit board, a printed circuit board, or a flexible film such as a chip on film.

The touch driver 400 may be mounted on the circuit board 300. The touch driver 400 may be connected to a touch sensing unit of the display panel 100. The touch driver 400 may supply touch driving signals to a plurality of touch electrodes of the touch sensing unit and sense change amounts in capacitance between the plurality of touch electrodes. For example, the touch driving signal may be a pulse signal having a predetermined frequency. The touch driver 400 may decide whether or not an input has occurred and calculate input coordinates, based on the change amounts in capacitance between the plurality of touch electrodes. The touch driver 400 may be formed as an integrated circuit (IC).

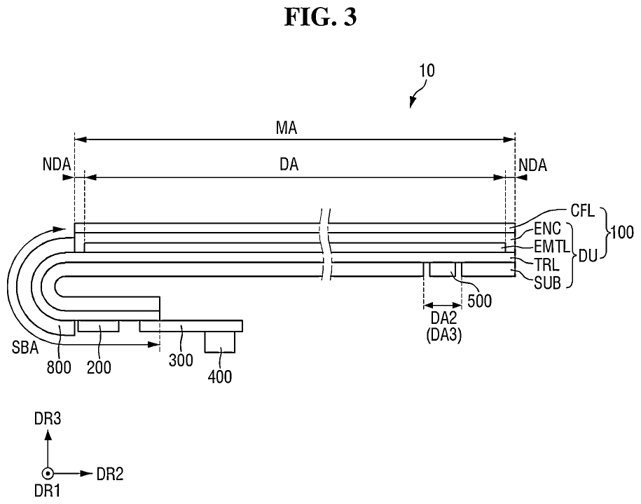

FIG. 3 is a cross-sectional view of the display device 10 of FIG. 2 viewed from the side.

Referring to FIG. 3, the display panel 100 may include a display layer DU and a color filter layer CFL. The display layer DU may include a substrate SUB, a transistor layer TRL, a light emitting element layer EMTL, and an encapsulation layer ENC.

The substrate SUB may be a base substrate or a base member. The substrate SUB may be a flexible substrate that may be bent, folded, and rolled. For example, the substrate SUB may include a polymer resin such as polyimide (PI), but is not limited thereto. In an exemplary embodiment, the substrate SUB may include a glass material or a metal material. In an exemplary embodiment, the substrate SUB may be a silicon substrate, a germanium substrate, or a silicon-germanium substrate.

The transistor layer TRL may be disposed on the substrate SUB. The transistor layer TRL may include a plurality of transistors constituting pixel circuits of pixels. The transistor layer TRL may further include gate lines, data lines, power lines, gate control lines, fan-out lines connecting the display driver 200 and the data lines to each other, and lead lines connecting the display driver 200 and the pad parts to each other. Each of the transistors may include a semiconductor region, a source electrode, a drain electrode, and a gate electrode. For example, when a gate driver is formed on one side of the non-display area NDA of the display panel 100, the gate driver may include transistors.

The transistor layer TRL may be disposed in the display area DA, the non-display area NDA, and the sub-area SBA. The transistors of each of the pixels, the gate lines, the data lines, and the power lines of the transistor layer TRL may be disposed in the display area DA. The gate control lines and the fan-out lines of the transistor layer TRL may be disposed in the non-display area NDA. The lead lines of the transistor layer TRL may be disposed in the sub-area SBA.

The light emitting element layer EMTL may be disposed on the transistor layer TRL. The light emitting element layer EMTL may include a plurality of light emitting elements each including a first electrode, a second electrode, and a light emitting layer to emit light and a pixel defining film defining the pixels. The plurality of light emitting elements of the light emitting element layer EMTL may be disposed in the display area DA.

In an exemplary embodiment, the light emitting layer may be an organic light emitting layer including an organic material. The light emitting layer may include a hole transporting layer, an organic light emitting layer, and an electron transporting layer. When the first electrode receives a voltage through the transistor of the transistor layer TRL and the second electrode receives a cathode voltage, holes and electrons may move to the organic light emitting layer through the hole transporting layer and the electron transporting layer, respectively, and may be combined with each other in the organic light emitting layer to emit light.

In an exemplary embodiment, the light emitting element may include a quantum dot light emitting diode including a quantum dot light emitting layer, an inorganic light emitting diode including an inorganic semiconductor, or a micro light emitting diode.

The encapsulation layer ENC may cover an upper surface and side surfaces of the light emitting element layer EMTL, and may protect the light emitting element layer EMTL. The encapsulation layer ENC may include at least one inorganic film and at least one organic film for encapsulating the light emitting element layer EMTL.

Although not illustrated in FIG. 3, in an exemplary embodiment, a touch layer may be further disposed on the encapsulation layer ENC. The touch layer may include a plurality of touch electrodes for sensing a user's touch in a capacitance manner and touch lines connecting the plurality of touch electrodes and the touch driver to each other. For example, the touch layer may sense the user's touch in a mutual capacitance manner or a self-capacitance manner. In an exemplary embodiment, the touch layer may be disposed on a separate substrate disposed on the display layer DU. In this case, the substrate supporting the touch layer may be a base member encapsulating the display layer DU.

The color filter layer CFL may be disposed on the encapsulation layer ENC. The color filter layer CFL may include a plurality of color filters each corresponding to the plurality of emission areas. Each of the color filters may selectively transmit light of a specific wavelength therethrough and block or absorb light of other wavelengths. The color filter layer CFL may absorb some of light introduced from the outside of the display device 10 to reduce reflected light by external light. Accordingly, the color filter layer CFL may prevent distortion of colors due to external light reflection.

Since the color filter layer CFL is directly disposed on the encapsulation layer ENC, the display device 10 may not require a separate substrate for the color filter layer CFL. Accordingly, a thickness of the display device 10 may be relatively small.

In some exemplary embodiments, the display device 10 may further include an optical device 500. The optical device 500 may be disposed in the second display area DA2 or the third display area DA3. The optical device 500 may emit or receive light of infrared, ultraviolet, and visible light bands. For example, the optical device 500 may be an optical sensor sensing light incident on the display device 10, such as a proximity sensor, an illuminance sensor, and a camera sensor or an image sensor.

Meanwhile, when the sub-area SBA is bent, as illustrated in FIG. 3, a protective layer 800 may be further disposed on a bent portion of the sub-area SBA.

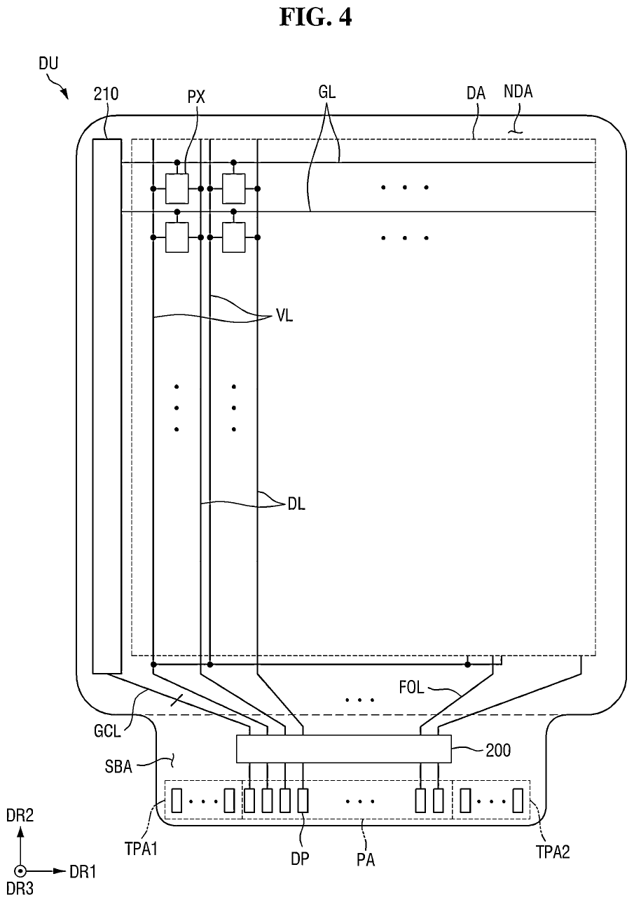

FIG. 4 is a plan view illustrating a display layer DU of the display device according to an exemplary embodiment.

Referring to FIG. 4, the display layer DU may include a display area DA and a non-display area NDA.

The display area DA may be disposed at the center of the display panel 100. A plurality of pixels PX, a plurality of gate lines GL, a plurality of data lines DL, and a plurality of power lines VL may be disposed in the display area DA. Each of the plurality of pixels PX may be defined as a minimum unit emitting light.

The plurality of gate lines GL may supply gate signals received from a gate driver 210 to the plurality of pixels PX. The plurality of gate lines GL may extend in the first direction DR1, and may be spaced apart from each other in the second direction DR2 crossing the first direction DR1.

The plurality of data lines DL may supply data voltages received from the display driver 200 to the plurality of pixels PX. The plurality of data lines DL may extend in the second direction DR2, and may be spaced apart from each other in the first direction DR1.

The plurality of power lines VL may supply source voltages received from the display driver 200 to the plurality of pixels PX. Here, the source voltage may be at least one of a driving voltage, an initialization voltage, a reference voltage, and a common voltage. The plurality of power lines VL may extend in the second direction DR2, and may be spaced apart from each other in the first direction DR1.

The non-display areas NDA may surround the display area DA. The gate driver 210, fan-out lines FOL, and gate control lines GCL may be disposed in the non-display area NDA. The gate driver 210 may generate a plurality of gate signals based on gate control signals, and may sequentially supply the plurality of gate signals to the plurality of gate lines GL according to a set order.

The fan-out lines FOL may extend from the display driver 200 to the display area DA. The fan-out lines FOL may supply the data voltages received from the display driver 200 to the plurality of data lines DL.

The gate control lines GCL may extend from the display driver 200 to the gate driver 210. The gate control lines GCL may supply the gate control signals received from the display driver 200 to the gate driver 210.

The sub-area SBA may include the display driver 200, a pad area PA, and first and second touch pad areas TPA1 and TPA2.

The display driver 200 may output signals and voltages for driving the display panel 100 to the fan-out lines FOL. The display driver 200 may supply the data voltages to the data lines DL through the fan-out lines FOL. The data voltages may be supplied to the plurality of pixels PX, and may control luminance of the plurality of pixels PX. The display driver 200 may supply the gate control signals to the gate driver 210 through the gate control lines GCL.

The pad area PA, the first touch pad area TPA1, and the second touch pad area TPA2 may be disposed at an edge of the sub-area SBA. The pad area PA, the first touch pad area TPA1, and the second touch pad area TPA2 may be electrically connected to the circuit board 300 using a material such as an anisotropic conductive film or a self assembly anisotropic conductive paste (SAP).

The pad area PA may include a plurality of display pad parts DP. The plurality of display pad parts DP may be connected to a graphic system through the circuit board 300. The plurality of display pad parts DP may be connected to the circuit board 300 to receive digital video data, and may supply the digital video data to the display driver 200.

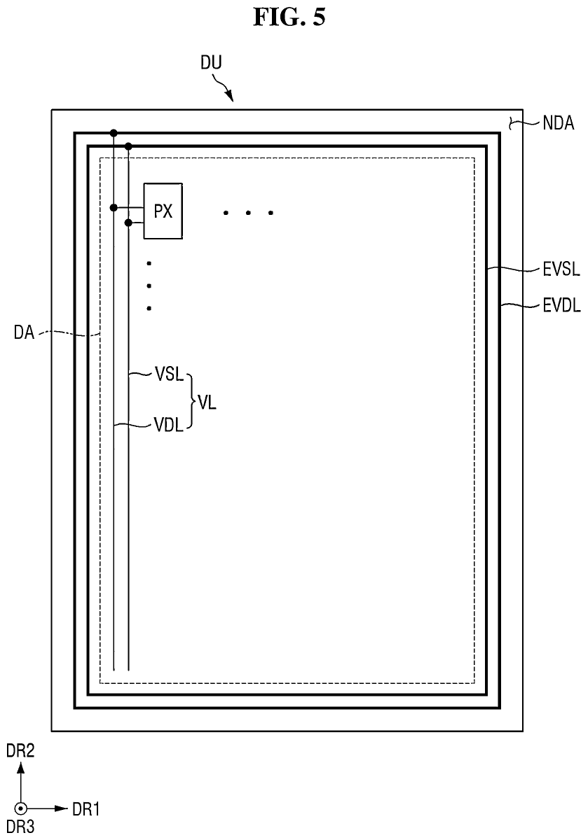

FIG. 5 is a plan view illustrating the display layer DU of the display device according to an exemplary embodiment.

Referring to FIG. 5, outer power lines EVDL and EVSL may be disposed in the non-display area NDA of the display layer DU. The outer power lines EVDL and EVSL may include, for example, an outer driving voltage line EVDL and an outer common voltage line EVSL.

The outer driving voltage line EVDL may be connected to the power line VL of the display area DA. For example, the outer driving voltage line EVDL may be connected to a driving voltage line VDL of the display area DA. In other words, the driving voltage line VDL of the display area DA may extend to the non-display area NDA to be connected to the outer driving voltage line EVDL described above. The outer driving voltage line EVDL may transmit a driving voltage. The driving voltage from the outer driving voltage line EVDL may be provided to the driving voltage line VDL of the display area, and the driving voltage from the driving voltage line VDL may be provided to the pixel PX. The outer driving voltage line EVDL may be disposed in the non-display area NDA so as to surround the display area DA and the outer common voltage line EVSL. The outer driving voltage line EVDL may have a ring shape in which it surrounds the display area DA and the outer common voltage line EVSL.

The outer common voltage line EVSL may be connected to the power line VL of the display area DA. For example, the outer driving voltage line EVDL may be connected to a common voltage line VSL of the display area DA. In other words, the common voltage line VSL of the display area DA may extend to the non-display area NDA to be connected to the outer common voltage line EVSL described above. The outer common voltage line EVSL may transmit a common voltage. The common voltage from the outer common voltage line EVSL may be provided to the common voltage line VSL of the display area DA, and the common voltage from the common voltage line VSL may be provided to the pixel PX. The outer common voltage line EVSL may be disposed in the non-display area NDA so as to surround the display area DA. The outer common voltage line EVSL may have a ring shape in which it surrounds the display area DA.

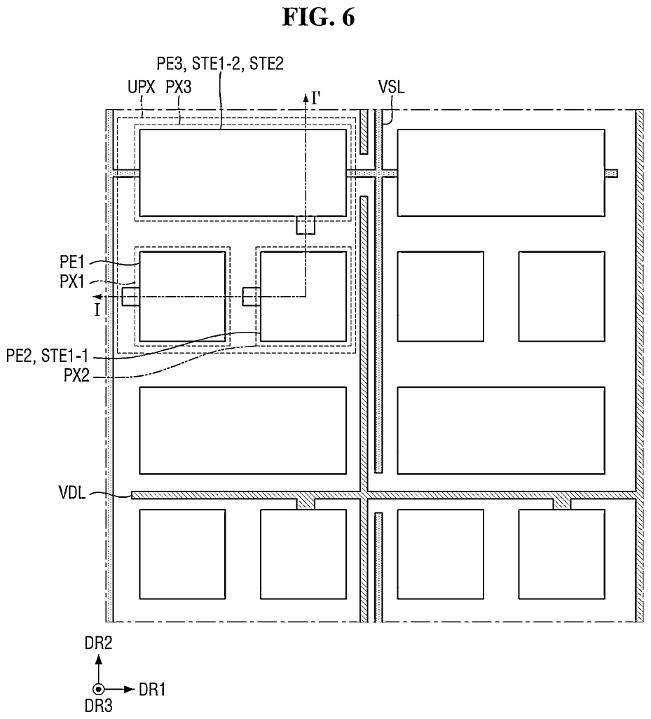

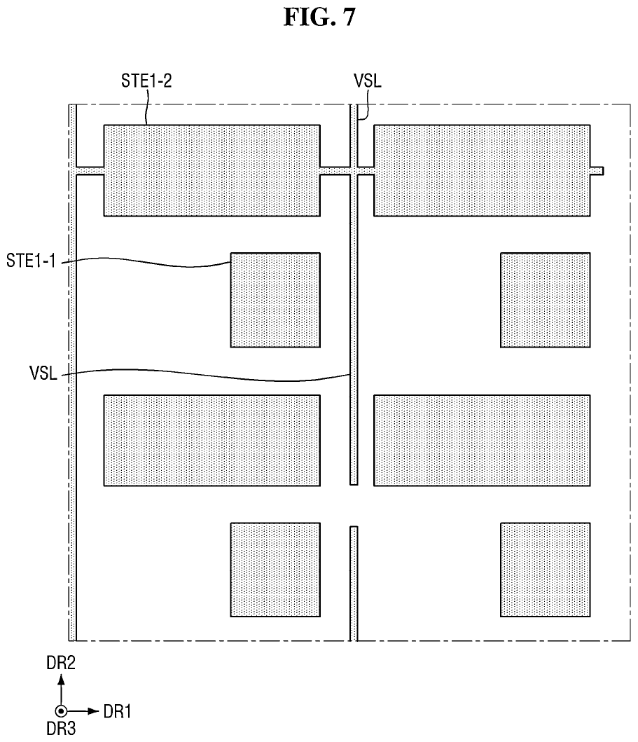

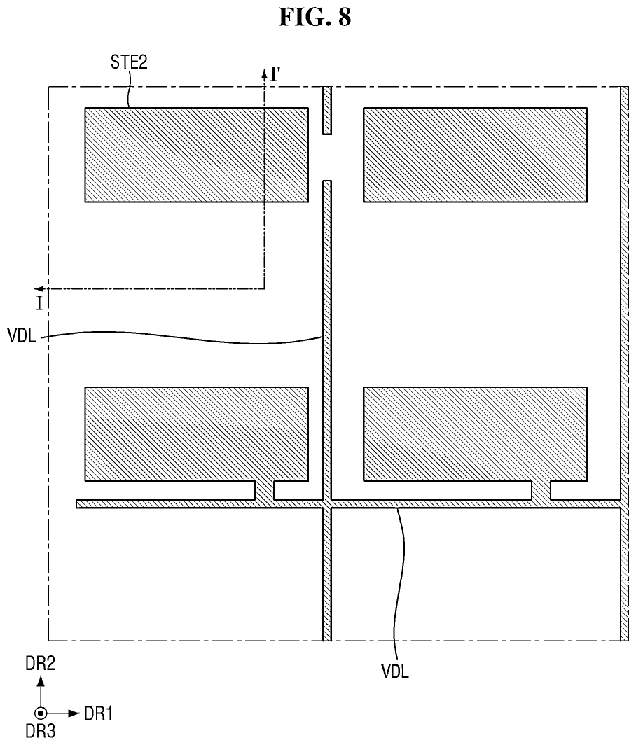

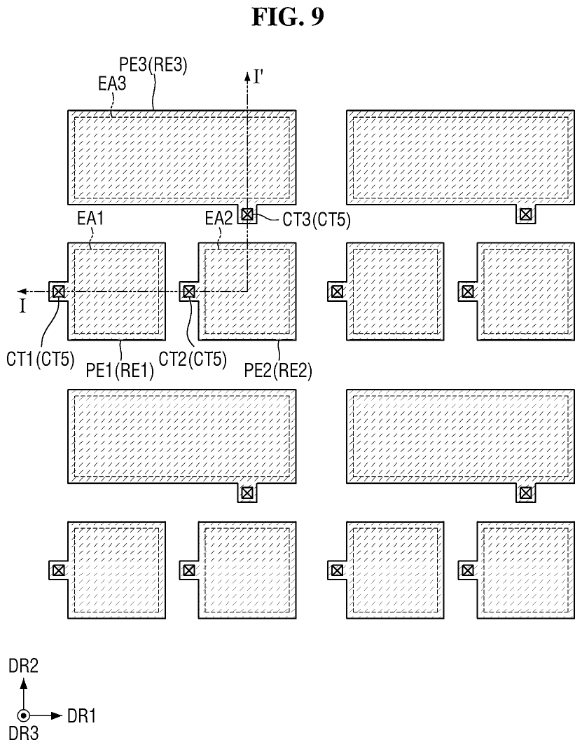

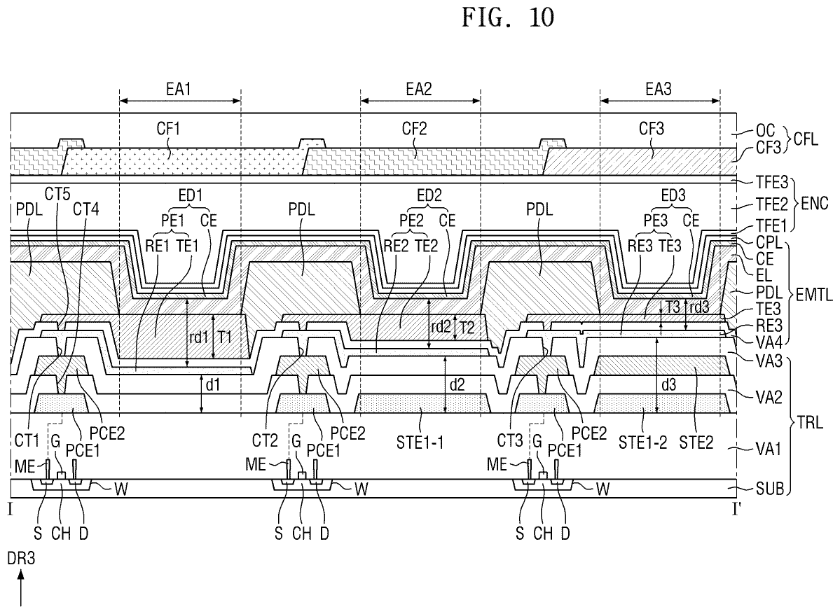

FIG. 6 is a plan view of first stepped electrodes, second stepped electrodes STE2, and pixel electrodes disposed in a display area of the display device according to an exemplary embodiment. FIG. 7 is a plan view of the first stepped electrodes of FIG. 6. FIG. 8 is a plan view of the second stepped electrodes STE2 of FIG. 6. FIG. 9 is a plan view of the pixel electrodes of FIG. 6. FIG. 10 is a cross-sectional view of the display device according to an exemplary embodiment taken along line I-I′ of FIG. 6.

As illustrated in FIGS. 6 and 9, one unit pixel UPX may include a first pixel electrode PE1, a second pixel electrode PE2, and a third pixel electrode PE3 disposed adjacent to each other.

The first pixel electrode PE1, the second pixel electrode PE2, and the third pixel electrode PE3 may be disposed adjacent to each other. For example, the first pixel electrode PE1 and the second pixel electrode PE2 may be disposed adjacent to each other in the first direction DR1, the second pixel electrode PE2 and the third pixel electrode PE3 may be disposed adjacent to each other in the second direction DR2, and the third pixel electrode PE3 and the first pixel electrode PE1 may be disposed adjacent to each other in the second direction DR2.

A portion of the first pixel electrode PE1 (e.g., an edge of the first pixel electrode PE1), a portion of the second pixel electrode PE2 (e.g., an edge of the second pixel electrode PE2), and a portion of the third pixel electrode PE3 (e.g., an edge of the third pixel electrode PE3) may be covered by a bank PDL (see FIG. 10) to be described later. In other words, a portion of the first pixel electrode PE1 (e.g., an edge of the first pixel electrode PE1), a portion of the second pixel electrode PE2 (e.g., an edge of the second pixel electrode PE2), and a portion of the third pixel electrode PE3 (e.g., an edge of the third pixel electrode PE3) may overlap the bank PDL described above.

The bank PDL may include a plurality of opening areas (hereinafter referred to as emission areas) penetrating therethrough, and such emission areas EA1, EA2, and EA3 may be disposed to correspond to the pixel electrodes PE1, PE2, and PE3 described above. For example, a first emission area EA1 of the bank PDL may overlap an area of the first pixel electrode PE1 excluding the edge of the first pixel electrode PE1, a second emission area EA2 of the bank PDL may overlap an area of the second pixel electrode PE2 excluding the edge of the second pixel electrode PE2, and a third emission area EA3 of the bank PDL may overlap an area of the third pixel electrode PE3 excluding an edge of the third pixel electrode PE3.

One unit pixel UPX may include a first pixel PX1, a second pixel PX2, and a third pixel PX3 that provide light of different colors. The first pixel electrode PE1 may be a component included in the first pixel PX1, the second pixel electrode PE2 may be a component included in the second pixel PX2, and the third pixel electrode PE3 may be a component included in the third pixel PX3.

The first pixel PX1 may provide light through the first emission area EA1 described above, the second pixel PX2 may provide light through the second emission area EA2 described above, and the third pixel PX3 may provide light through the second emission area EA3 described above.

Referring to FIG. 10, the display device may include the transistor layer TRL, the light emitting element layer EMTL, the encapsulation layer ENC, and the color filter layer CFL.

The substrate SUB may be, for example, a silicon substrate, a germanium substrate, or a silicon-germanium substrate. The substrate SUB may be a substrate doped with first-type impurities.

Well regions W may be disposed on the substrate SUB (or inside the substrate SUB). The well regions W may be regions doped with second-type impurities. The second-type impurities may be different from the first-type impurities described above. For example, when the first-type impurities are p-type impurities, the second-type impurities may be n-type impurities. On the other hand, when the first-type impurities are n-type impurities, the second-type impurities may be p-type impurities.

A source region S, a drain region D, and a channel region CH of a transistor TR may be disposed in the well region W. For example, a source region S (or a source electrode) and a drain region D (or a drain electrode) of the transistor TR may be disposed in the well region W. Each of the source region S and the drain region D may be a region doped with the first-type impurities described above. A gate electrode G of the transistor TR may overlap the well region W while crossing the well region W. In plan view, the well region W crossing the gate electrode G may be defined as two regions, the source region S may be disposed in any one of the two regions, and the drain region D may be disposed in the other of the two regions. In other words, in the well region W, the source region S and the drain region D may be disposed on both sides of the gate electrode G, respectively, with the gate electrode G interposed therebetween. The channel region CH of the transistor may be disposed in a region of the well region W overlapping the gate electrode G.

Meanwhile, the source region S may include a first low-concentration impurity region having a relatively lower impurity concentration than other portions of the source region S. In other words, a portion of the source region S may include impurities at a lower concentration than other portions of the source region S. The drain region D may include a second low-concentration impurity region having a relatively lower impurity concentration than other portions of the drain region D. In other words, a portion of the drain region D may include impurities at a lower concentration than other portions of the drain region D.

The first low-concentration impurity region and the second low-concentration impurity region may be disposed close to the channel region CH of the transistor TR. For example, the first low-concentration impurity region may be disposed close to the channel region CH so as to overlap a first spacer disposed on one side of the gate electrode G, and the second low-concentration impurity region may be disposed close to the channel region CH so as to overlap a second spacer disposed on the other side of the gate electrode G. As such, a distance between a high-concentration impurity region of the source region S and a high-concentration impurity region of the drain region D may be increased by the first low-concentration impurity region and the second low-concentration impurity region, and as the distance is increased, a length of the channel area CH may be eventually increased. Accordingly, punch-through and hot carrier phenomena caused by a short channel may be prevented.

A first interlayer insulating film VA1 may be disposed on the substrate SUB. Here, the first interlayer insulating film VA1 may include a plurality of insulating films that are sequentially stacked along the third direction DR3. Metal layers may be disposed between the respective insulating films. These metal layers may include, for example, the gate lines and the data lines described above, capacitor electrodes, and the like.

First pixel connection electrodes PCE1, a first-first stepped electrode STE1-1, and a first-second stepped electrode STE1-2 may be disposed on the first interlayer insulating film VA1. The first pixel connection electrodes PCE1, the first-first stepped electrode STE1-1, and the first-second stepped electrode STE1-2 may be disposed on the same layer. The first pixel connection electrodes PCE1, the first-first stepped electrode STE1-1, and the first-second stepped electrode STE1-2 may be made of the same material.

The first pixel connection electrode PCE1 may be disposed on the first interlayer insulating film VA1 so as to overlap the bank PDL. The first pixel connection electrode PCE1 may be connected to the source region S of the transistor TR through contact holes penetrating through the insulating films of the first interlayer insulating film VA1 and a plurality of metal layers.

The first-second stepped electrode STE1-2 may be disposed on the first interlayer insulating film VA1 so as to overlap the third emission area EA3. As illustrated in FIG. 7, the first-second stepped electrode STE1-2 may be connected to the power line VL. For example, the first-second stepped electrode STE1-2 may be connected to the common voltage line VSL (and/or the outer common voltage line EVSL) described above. The first-second stepped electrode STE1-2 and the common voltage line VSL (and/or the outer common voltage line EVSL) may be formed integrally with each other. The first-second stepped electrode STE1-2 may be disposed on the same layer as the common voltage line VSL (and/or the outer common voltage line EVSL). The first-second stepped electrode STE1-2 may be made of the same material as the common voltage line VSL (and/or the outer common voltage line EVSL). The first-second stepped electrode STE1-2 may have a quadrangular shape.

The first-first stepped electrode STE1-1 may be disposed on the first interlayer insulating film VA1 so as to overlap the second emission area EA2. As illustrated in FIG. 7, the first-first stepped electrode STE1-1 may be in a floating state. However, the present disclosure is not limited thereto, and the first-first stepped electrode STE1-1 may be connected to the power line VL. For example, the first-first stepped electrode STE1-1 may be connected to the common voltage line VSL (and/or the outer common voltage line EVSL). The first-first stepped electrode STE1-1 and the common voltage line VSL (and/or the outer common voltage line EVSL) may be formed integrally with each other. The first-first stepped electrode STE1-1 may be disposed on the same layer as the common voltage line VSL (and/or the outer common voltage line EVSL). The first-first stepped electrode STE1-1 may be made of the same material as the common voltage line VSL (and/or the outer common voltage line EVSL). The first-first stepped electrode STE1-1 may have a quadrangular shape.

Meanwhile, the first pixel connection electrode PCE1, the first-first stepped electrode STE1-1, the first-second stepped electrode STE1-2, the common voltage line VSL, and the outer common voltage line EVSL may all be disposed on the same layer. In addition, the first pixel connection electrode PCE1, the first-first stepped electrode STE1-1, the first-second stepped electrode STE1-2, the common voltage line VSL, and the outer common voltage line EVSL may all be made of the same material.

A second interlayer insulating film VA2 may be disposed on the first pixel connection electrodes PCE1, the first-first stepped electrode STE1-1, and the first-second stepped electrode STE1-2.

Second pixel connection electrodes PCE2 and a second stepped electrode STE2 may be disposed on the second interlayer insulating film VA2.

The second pixel connection electrodes PCE2 may be disposed on the second interlayer insulating film VA2 so as to overlap the first pixel connection electrodes PCE1. The second pixel connection electrodes PCE2 may be connected to the first pixel connection electrodes PCE1 through fourth contact holes CT4 penetrating through the second interlayer insulating film VA2.

The second stepped electrode STE2 may be disposed on the second interlayer insulating film VA2 so as to overlap the third emission area EA3. For example, the second stepped electrode STE2 may overlap the first-second stepped electrode STE1-2 in the third emission area EA3. The second stepped electrode STE2 may overlap the entirety of the first-second stepped electrode STE1-2. In this case, an area of the second stepped electrode STE2 and an area of the first-second stepped electrode STE1-2 may be the same as each other. However, the present disclosure is not limited thereto, and an area of the second stepped electrode STE2 and an area of the first-second stepped electrode STE1-2 may be different from each other. Areas of the stepped electrodes may be defined by sizes of the stepped electrodes in the first direction DR1 and sizes of the stepped electrodes in the second direction DR2.

The second stepped electrode STE2 may be maintained in a floating state. However, the present disclosure is not limited thereto, and the second stepped electrode STE2 may be connected to the power line VL. For example, the second stepped electrode STE2 may be connected to the driving voltage line VDL (or the outer driving voltage line EVDL) described above. The second stepped electrode STE2 and the driving voltage line VDL (or the outer driving voltage line EVDL) may be formed integrally with each other. The second stepped electrode STE2 may be disposed on the same layer as the driving voltage line VDL (or the outer driving voltage line EVDL). The second stepped electrode STE2 may be made of the same material as the driving voltage line VDL (or the outer driving voltage line EVDL). The second stepped electrode STE2 may have a quadrangular shape.

Meanwhile, the second pixel connection electrode PCE2, the second stepped electrode STE2, the driving voltage line, and the outer driving voltage line EVDL may all be disposed on the same layer. In addition, the second pixel connection electrode PCE2, the second stepped electrode STE2, the driving voltage line, and the outer driving voltage line EVDL may all be made of the same material.

A third interlayer insulating film VA3 may be disposed on the second pixel connection electrodes PCE2 and the second stepped electrode STE2.

The light emitting element layer EMTL may be disposed on the third interlayer insulating film VA3. The light emitting element layer EMTL may include, for example, a first light emitting element ED1, a second light emitting element ED2, and a third light emitting element ED3 disposed in different emission areas. For example, the first light emitting element ED1 of the light emitting element layer EMTL may be disposed in the first emission area EA1, the second light emitting element ED2 of the light emitting element layer EMTL may be disposed in the second emission area EA2, and the third light emitting element ED3 of the light emitting element layer EMTL may be disposed in the third emission area EA3.

Each of the first light emitting element ED1, the second light emitting element ED2, and the third light emitting element ED3 may provide white light.

The first light emitting element ED1 may include the first pixel electrode PE1 (or a first anode electrode), a light providing layer EL, and a common electrode CE that are stacked in the third direction DR3.

The second light emitting element ED2 may include the second pixel electrode PE2 (or a second anode electrode), the light providing layer EL, and the common electrode CE that are stacked in the third direction DR3.

The third light emitting element ED3 may include the third pixel electrode PE3 (or a third anode electrode), the light providing layer EL, and the common electrode CE that are stacked in the third direction DR3.

Here, the light providing layer EL and the common electrode CE may be common layers used in common for the respective light emitting elements ED1, ED2, and ED3. In other words, a plurality of light emitting elements ED1, ED2, and ED3 of the light emitting element layer EMTL may share the light providing layer EL and the common electrode CE with each other.

The light providing layer EL may include a plurality of light emitting layers providing light of different colors, and the plurality of light emitting layers may be stacked along the third direction DR3. The plurality of light emitting layers may include, for example, a red light emitting layer, a green light emitting layer, and a blue light emitting layer that are stacked in the third direction DR3. Different light from the plurality of light emitting layers may be mixed with each other to generate white light. Meanwhile, the light providing layer EL may further include charge generation layers. The charge generation layers may be disposed between adjacent light emitting layers. As such, the light providing layer EL may have a tandem structure including the plurality of light emitting layers and the charge generation layers.

The first pixel electrode PE1, the second pixel electrode PE2, and the third pixel electrode PE3 may be connected to the respective source regions S of the respective transistors TR through the first pixel connection electrodes PCE1, the second pixel connection electrodes PCE2, and metal connection layers ME.

The second pixel electrode PE2 may overlap the second emission area EA2. In addition, the second pixel electrode PE2 may overlap the first-first stepped electrode STE1-1 in the second emission area EA2.

The third pixel electrode PE3 may overlap the third emission area EA3. In addition, the third pixel electrode PE3 may overlap the first-second stepped electrode STE1-2 and the second stepped electrode STE2 in the third emission area EA3.

Each of the pixel electrodes PE1, PE2, and PE3 may include a reflective electrode and a light-transmitting electrode. For example, as illustrated in FIG. 10, the first pixel electrode PE1 may include a first reflective electrode RE1 and a first light-transmitting electrode TE1 connected to each other through a fifth contact hole CT5 of a fourth interlayer insulating film VA4. The second pixel electrode PE2 may include a second reflective electrode RE2 and a second light-transmitting electrode TE2 connected to each other through a fifth contact hole CT5 of the fourth interlayer insulating film VA4. The third pixel electrode PE3 may include a third reflective electrode RE3 and a third light-transmitting electrode TE3 connected to each other through a fifth contact hole CT5 of the fourth interlayer insulating film VA4.

The reflective electrodes RE1, RE2, and RE3 may be disposed on the third interlayer insulating film VA3 so as to overlap the emission areas EA1, EA2, and EA3, respectively. For example, the first reflective electrode RE1 may be disposed on the third interlayer insulating film VA3 so as to overlap the first emission area EA1, the second reflective electrode RE2 may be disposed on the third interlayer insulating film VA3 so as to overlap the second emission area EA2, and the third reflective electrode RE3 may be disposed on the third interlayer insulating film VA3 so as to overlap the third emission area EA3.

The respective reflective electrodes RE1, RE2, and RE3 may be connected to the respective second pixel connection electrodes PCE2 through respective contact holes CT1, [symbol] [symbol] [symbol] [symbol] CT2, and CT3 penetrating through the third interlayer insulating film VA3. For example, the first reflective electrode RE1 may be connected to the second pixel connection electrode PCE2 disposed therebelow through a first contact hole CT1 penetrating through the third interlayer insulating film VA3. The second reflective electrode RE2 may be connected to the second pixel connection electrode PCE2 disposed there below through a second contact hole CT2 penetrating through the third interlayer insulating film VA3. The third reflective electrode RE3 may be connected to the second pixel connection electrode PCE2 disposed therebelow through a third contact hole CT3 penetrating through the third interlayer insulating film VA3.

The second reflective electrode RE2 may overlap the second emission area EA2. The second reflective electrode RE2 may overlap the first-first stepped electrode STE1-1 in the second emission area EA2.

The third reflective electrode RE3 may overlap the third emission area EA3. The third reflective electrode RE3 may overlap the first-second stepped electrode STE1-2 and the second stepped electrode STE2 in the third emission area EA3.

As illustrated in FIG. 10, the numbers of stepped electrodes disposed in the respective emission areas EA1, EA2, and EA3 of one unit pixel UPX (e.g., the numbers of stacked stepped electrodes overlapping the respective emission areas EA1, EA2, and EA3 in the third direction DR3) are different from each other, and thus, distances between the reflective electrodes RE1, RE2, and RE3 and the common electrode CE may be different from each other for each pixel.

For example, a stepped electrode may not be disposed in the first emission area EA1 (e.g., the number of stepped electrodes in the first emission area EA1 may be 0), one stepped electrode STE1-1 may be disposed in the second emission area EA2, and two stepped electrodes STE1-2 and STE2 may be disposed in the third emission area EA3. Specifically, a stepped electrode may not be disposed between the first reflective electrode RE1 and the first interlayer insulating film VA1 (e.g., the uppermost insulating film of the first interlayer insulating film VA1) in the first emission area EA1, one stepped electrode STE1-1 may be disposed between the second reflective electrode RE2 and the first interlayer insulating film VA1 (e.g., the uppermost insulating film of the first interlayer insulating film VA1) in the second emission area EA2, and two stepped electrodes STE1-2 and STE2 may be disposed between the third reflective electrode RE3 and the first interlayer insulating film VA1 (e.g., the uppermost insulating film of the first interlayer insulating film VA1) in the third emission area EA3 so as to overlap each other in the third direction DR3. In other words, a stepped electrode overlapping the first reflective electrode RE1 may not exist between the first reflective electrode RE1 of the first emission area EA1 and the first interlayer insulating film VA1 (e.g., the uppermost insulating film of the first interlayer insulating film VA1). One stepped electrode STE1-1 overlapping the second reflective electrode RE2 in the third direction DR3 may exist between the second reflective electrode RE2 of the second emission area EA2 and the first interlayer insulating film VA1 (e.g., the uppermost insulating film of the first interlayer insulating film VA1). Two stepped electrodes STE1-2 and STE2 overlapping the third reflective electrode RE3 in the third direction DR3 may exist between the third reflective electrode RE3 of the third emission area EA3 and the first interlayer insulating film VA1 (e.g., the uppermost insulating film of the first interlayer insulating film VA1). Here, the uppermost insulating film of the first interlayer insulating film VA1 may refer to an insulating film disposed farthest from the substrate SBU in the third direction DR3 among the plurality of insulating films included in the first interlayer insulating film VAL. In other words, the uppermost insulating film of the first interlayer insulating film VA1 may be an insulating film closest to the second interlayer insulating film VA2 in the third direction DR3 among the insulating films of the first interlayer insulating film VA1.

Since the numbers of stacked stepped electrodes disposed below the respective reflective electrodes RE1, RE2, and RE3 of one unit pixel UPX are different from each other as described above, distances between the first interlayer insulating film VA1 (e.g., the uppermost insulating film of the first interlayer insulating film VA1) and the respective reflective electrodes RE1, RE2, and RE3 may be different from each other. For example, a distance d1 between the first interlayer insulating film VA1 (e.g., the uppermost insulating film of the first interlayer insulating film VA1) and the first reflective electrode RE1 (hereinafter referred to as a first distance), a distance d2 between the first interlayer insulating film VA1 (e.g., the uppermost insulating film of the first interlayer insulating film VA1) and the second reflective electrode RE2 (hereinafter referred to as a second distance), and a distance d3 between the first interlayer insulating film VA1 (e.g., the uppermost insulating film of the first interlayer insulating film VA1) and the third reflective electrode RE3 (hereinafter referred to as a third distance) may be defined by Relational Expression 1.

d1<d2<d3 <Relational Expression 1>

That is, as defined in Relational Expression 1, the second distance d2 is greater than the first distance d1 and smaller than the third distance d3. In other words, as the number of stacked stepped electrodes overlapping the reflective electrode in the third direction DR3 increases, a distance between the reflective electrode and the uppermost insulating film of the first interlayer insulating film VA1 may increase.

In addition, since the numbers of stacked stepped electrodes disposed below the respective reflective electrodes RE1, RE2, and RE3 of one unit pixel UPX are different from each other as described above, distances between the respective reflective electrodes RE1, RE2, and RE3 and the common electrode CE may be different from each other. For example, as the number of stacked stepped electrodes overlapping the reflective electrode in the third direction DR3 increases, a distance between the reflective electrode and the common electrode CE may decrease. For example, a distance rd1 between the first reflective electrode RE1 and the common electrode CE (hereinafter referred to as a first distance), a distance rd2 between the second reflective electrode RE2 and the common electrode CE (hereinafter referred to as a second distance), and a distance rd3 between the third reflective electrode RE3 and the common electrode CE (hereinafter referred to as a third distance) may be defined by Relational Expression 2.

rd1>rd2>rd3 <Relational Expression 2>

That is, as defined in Relational Expression 2, the second distance rd2 is smaller than the first distance rd1 and greater than the third distance rd3. This is because the distance between the reflective electrode and the uppermost insulating film of the first interlayer insulating film VA1 increases as the number of stacked stepped electrodes overlapping the reflective electrode in the third direction DR3 increases. For example, the first reflective electrode RE1 of the reflective electrodes RE1, RE2, and RE3 disposed in one unit pixel UPX may be disposed closest to the first interlayer insulating film VA1 (e.g., the uppermost insulating film of the first interlayer insulating film VA1) in the third direction DR3, and the third reflective electrode RE3 of the reflective electrodes RE1, RE2, and RE3 disposed in one unit pixel UPX may be disposed farthest from the first interlayer insulating film VA1 (e.g., the uppermost insulating film of the first interlayer insulating film VA1). Meanwhile, the second reflective electrode RE2 may be disposed at a level higher than the first reflective electrode RE1 and lower than the third reflective electrode RE3 in the third direction DR3.

Meanwhile, distances between the respective reflective electrodes RE1, RE2, and RE3 and the common electrode CE may refer to, for example, sizes in the third direction DR3. In this case, the distances between the respective reflective electrodes RE1, RE2, and RE3 and the common electrode CE may be distances in the third direction DR3 between the lowest portions of the common electrode CE and the respective reflective electrodes in the corresponding emission areas. For example, the distance between the first reflective electrode RE1 and the common electrode CE may be defined as a distance between the lowest portion of the common electrode CE and the first reflective electrode RE1 in the third direction DR3 in the first emission area EA1. Similarly, the distance between the second reflective electrode RE2 and the common electrode CE may be defined as a distance between the lowest portion of the common electrode CE and the second reflective electrode RE2 in the third direction DR3 in the second emission area EA2. Similarly, the distance between the third reflective electrode RE3 and the common electrode CE may be defined as a distance between the lowest portion of the common electrode CE and the third reflective electrode RE3 in the third direction DR3 in the third emission area EA3.

The distances between the common electrode CE and the respective reflective electrodes RE1, RE2, and RE3 described above may be defined as resonance distances. For example, the distance between the first reflective electrode RE1 and the common electrode CE may be defined as a first resonance distance rd1, the distance between the second reflective electrode RE2 and the common electrode CE may be defined as a second resonance distance rd2, and the distance between the third reflective electrode RE3 and the common electrode CE may be defined as a third resonance distance rd3.

In an exemplary embodiment, since the numbers of stacked stepped electrodes are different from each other for each pixel, the resonance distances rd1, rd2, and rd3 between the reflective electrodes and the common electrode CE for each pixel may be adjusted to be different from each other. Accordingly, a micro-cavity (or thin film resonance) effect on light may be increased and/or optimized according to a wavelength of light to be emitted from each pixel and a resonance distance, a resonance order, and the like, corresponding to the wavelength. For example, light of a first color, light of a second color, and light of a third color may be appropriately amplified in the first emission area EA1, the second emission area EA2, and the third emission area EA3, respectively. As an example, the light of the first color emitted through the first emission area EA1 may be red light corresponding to a first color filter CF1 to be described later, the light of the second color emitted through the second emission area EA2 may be green light corresponding to a second color filter CF2 to be described later, and the light of the third color emitted through the third emission area EA3 may be blue light corresponding to a third color filter CF3 to be described later. In other words, the resonance distance rd2 of the second emission area EA2 from which the green light is emitted may be smaller than the resonance distance rd1 of the first emission area EA1 from which the red light is emitted and be greater than the resonance distance rd3 of the third emission area EA3 through which the blue light is emitted.

In an exemplary embodiment, the reflective electrodes RE1, RE2, and RE3 may be metal layers including a metal such as silver (Ag), magnesium (Mg), aluminum (Al), platinum (Pt), palladium (Pd), gold (Au), nickel (Ni), neodymium (Nd), iridium (Ir), chromium (Cr), or compounds thereof. In an exemplary embodiment, the reflective electrodes RE1, RE2, and RE3 may further include metal oxide layers (e.g., transparent conductive oxide layers) positioned above and/or below the metal layers. As an example, each of the reflective electrodes RE1, RE2, and RE3 may have a double-layer structure of indium tin oxide (ITO)/Ag, Ag/ITO, ITO/Mg, or ITO/MgF, or a triple-layer structure such as ITO/Ag/ITO.

The fourth interlayer insulating film VA4 may be disposed on the respective reflective electrodes RE1, RE2, and RE3. The fourth interlayer insulating film VA4 may include an inorganic film.

The first light-transmitting electrode TE1, the second light-transmitting electrode TE2, and the third light-transmitting electrode TE3 may be disposed on the fourth interlayer insulating film VA4.

The first light-transmitting electrode TE1 may be disposed on the fourth interlayer insulating film VA4 so as to overlap the first emission area EA1. The first light-transmitting electrode TE1 may overlap the first reflective electrode RE1 in the first emission area EA1. The first light-transmitting electrode TE1 may be connected to the first reflective electrode RE1 through the fifth contact hole CT5 penetrating through the fourth interlayer insulating film VA4.

The second light-transmitting electrode TE2 may be disposed on the fourth interlayer insulating film VA4 so as to overlap the second emission area EA2. The second light-transmitting electrode TE2 may overlap the second reflective electrode RE2 and the first-first stepped electrode STE1-1 in the second emission area EA2. The second light-transmitting electrode TE2 may be connected to the second reflective electrode RE2 through the fifth contact hole CT5 penetrating through the fourth interlayer insulating film VA4.

The third light-transmitting electrode TE3 may be disposed on the fourth interlayer insulating film VA4 so as to overlap the third emission area EA3. The third light-transmitting electrode TE3 may overlap the third reflective electrode RE3, the second stepped electrode STE2, and the first-second stepped electrode STE1-2 in the third emission area EA3. The third light-transmitting electrode TE3 may be connected to the third reflective electrode RE3 through the fifth contact hole CT5 penetrating through the fourth interlayer insulating film VA4.

The respective light-transmitting electrodes TE1, TE2, and TE3 described above may have different thicknesses. For example, as the number of stacked stepped electrodes overlapping the reflective electrode in the third direction DR3 increases, the light-transmitting electrode connected to the reflective electrode may have a smaller thickness. For example, a thickness of the first light-transmitting electrode TE1 (hereinafter referred to as a first thickness T1), a thickness of the second light-transmitting electrode TE2 (hereinafter referred to as a second thickness T2), and a thickness of the third light-transmitting electrode TE3 (hereinafter referred to as a third thickness T3) may be defined by Relational Expression 3.

T1>T2>T3 <Relational Expression 3>

That is, as defined in Relational Expression 3, the second thickness T2 is smaller than the first thickness T1 and greater than the third thickness T3. In other words, a thickness of the light-transmitting electrode may be proportional to a distance between the reflective electrode connected to the light-transmitting electrode and the common electrode CE. Here, a thickness of each of the light-transmitting electrodes TE1, TE2, and TE3 may refer to, for example, a size of each of the light-transmitting electrodes TE1, TE2, and TE3 in the third direction DR3 in the corresponding emission area. In other words, the thickness of each of the light-transmitting electrodes TE1, TE2, and TE3 may be a size of each of the light-transmitting electrodes measured in the third direction DR3. For example, the first thickness T1 may be a size of the first light-transmitting electrode TE1 in the third direction DR3 in the first emission area EA1, the second thickness T2 may be a size of the second light-transmitting electrode TE2 in the third direction DR3 in the second emission area EA2, and the third thickness T3 may be a size of the third light-transmitting electrode TE3 in the third direction DR3 in the third emission area EA3.

The light-transmitting electrodes TE1, TE2, and TE3 may include a transparent conductive material. For example, the light-transmitting electrodes TE1, TE2, and TE3 may include transparent conductive oxide (TCO). As an example, the light-transmitting electrodes TE1, TE2, and TE3 may include at least one of indium tin oxide (ITO), indium zinc oxide (IZO), indium gallium oxide (IGO), aluminum zinc oxide (AZO), zinc oxide (ZnO), indium oxide (In₂O₃), indium tin zinc oxide (ITZO), tungsten oxide (WₓOₓ), titanium oxide (TiO₂), and magnesium oxide (MgO), or other transparent conductive materials.

The bank PDL (or a pixel defining film) may be disposed on the first light-transmitting electrode TE1, the second light-transmitting electrode TE2, and the third light-transmitting electrode TE3.

The bank PDL may define the respective emission areas of the respective pixels PX1, PX2, and PX3 (e.g., the first emission area EA1 of the first pixel PX1, the second emission area EA2 of the second pixel PX2, and the third emission area EA3 of the third pixel PX3). To this end, the bank PDL may be disposed to expose, for example, partial areas of the first light-transmitting electrode TE1, the second light-transmitting electrode TE2, and the third light-transmitting electrode TE3 on the fourth interlayer insulating film VA4. The bank PDL may cover edges of the first light-transmitting electrode TE1, the second light-transmitting electrode TE2, and the third light-transmitting electrode TE3. The bank PDL may be formed as an organic film made of an acrylic resin, an epoxy resin, a phenolic resin, a polyamide resin, a polyimide resin, or the like.

The light providing layer EL may be disposed on the respective light-transmitting electrodes TE1, TE2, and TE3 and the bank PDL. For example, the light providing layer EL may be disposed on the first light-transmitting electrode TE1, the second light-transmitting electrode TE2, the third light-transmitting electrode TE3, and the bank PDL.

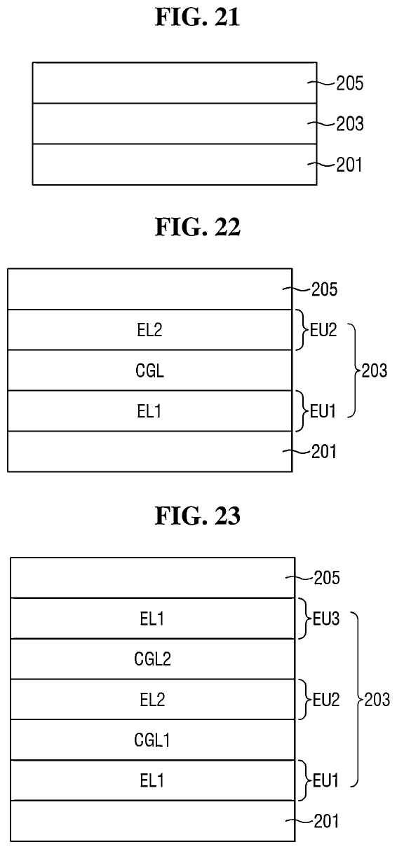

The light providing layer EL may include a plurality of light emitting units (see FIGS. 21 to 27). For example, the light providing layer EL may include a first light emitting unit, a second light emitting unit, and a third light emitting unit that are stacked in the third direction DR3. The respective light emitting units may provide light of different wavelengths. For example, the first light emitting unit, the second light emitting unit, and the third light emitting unit may emit light of different colors. For example, the light providing layer EL may have a tandem structure in which a plurality of light emitting units providing light of different colors are stacked in a vertical direction (e.g., the third direction DR3).

The first light emitting unit may be disposed on each light-transmitting electrode. The first light emitting unit may include a first light emitting layer, a hole transporting layer, an organic material layer, and an electron transporting layer.

The second light emitting unit may be disposed on the first light emitting unit. The second light emitting unit may include a second light emitting layer, a hole transporting layer, an organic material layer, and an electron transporting layer.

The third light emitting unit may be disposed on the second light emitting unit. The third light emitting unit may include a third light emitting layer, a hole transporting layer, an organic material layer, and an electron transporting layer.

The respective light emitting elements ED1, ED2, and ED3 may provide white light by mixing light of a first color (e.g., blue light) from the first light emitting unit, light of a second color (e.g., red light) from the second light emitting unit, and light of a third color (e.g., green light) from the third light emitting unit with each other. For example, each of the first light emitting element ED1, the second light emitting element ED2, and the third light emitting element ED3 may provide white light.

In addition, the light providing layer EL may further include at least one charge generation layer in addition to the light emitting units described above. The charge generation layer may be disposed between light emitting units adjacent to each other in the third direction DR3, for example. The charge generation layer may include, for example, a first charge generation layer and a second charge generation layer stacked in the third direction DR3. In such a case, the first charge generation layer may be disposed between the first light emitting unit and the second light emitting unit, and the second charge generation layer may be disposed between the second light emitting unit and the third light emitting unit.

Meanwhile, each charge generation layer may include a negative charge generation layer and a positive charge generation layer. For example, the first charge generation layer may include a first negative charge generation layer and a first positive charge generation layer stacked in the third direction DR3, and the second charge generation layer may include a second negative charge generation layer and a second positive charge generation layer stacked in the third direction DR3.

The common electrode CE may be disposed on the light providing layer EL. For example, the common electrode CE may be disposed on the light providing layer EL so as to overlap the first light-transmitting electrode TE1, the second light-transmitting electrode TE2, the third light-transmitting electrode TE3, the first emission area EA1, the second emission area EA2, the third emission area EA3, and the bank PDL. In a top emission structure, the common electrode CE may be made of a transparent conductive material (TCO) such as ITO or IZO capable of transmitting light therethrough or a semi-transmissive conductive material such as magnesium (Mg), silver (Ag), or an alloy of magnesium (Mg) and silver (Ag). When the common electrode CE is made of the semi-transmissive conductive material, emission efficiency may be increased by a micro cavity.

A capping layer CPL may be disposed on the common electrode CE. The capping layer CPL may include an inorganic insulating material. In an exemplary embodiment, the capping layer CPL may include aluminum oxide, titanium oxide, tantalum oxide, hafnium oxide, zinc oxide, silicon oxide, silicon nitride, and/or silicon oxynitride.

The encapsulation layer ENC may be disposed on the capping layer CPL. The encapsulation layer ENC may cover an upper surface and side surfaces of the light emitting element layer EMTL, and may protect the light emitting element layer EMTL. The encapsulation layer ENC may include at least one inorganic film and at least one organic film for encapsulating the light emitting element layer EMTL. The encapsulation layer ENC may include at least one inorganic film TFE1 or TFE3 in order to prevent oxygen or moisture from permeating into the light emitting element layer EMTL. In addition, the encapsulation layer ENC may include at least one organic film in order to protect the light emitting element layer EMTL from foreign substances such as dust. For example, the encapsulation layer ENC may include the first encapsulation inorganic film TFE1, an encapsulation organic film TFE2, and the second encapsulation inorganic film TFE3.

The first encapsulation inorganic film TFE1 may be disposed on the capping layer CPL, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of an acrylic resin, an epoxy resin, a phenolic resin, a polyamide resin, a polyimide resin, or the like.

The display device 10 may include the plurality of color filters CF1, CF2, and CF3 disposed on the emission areas EA1, EA2, and EA3. The plurality of color filters CF1, CF2, and CF3 may be disposed to correspond to the emission areas EA1, EA2, and EA3, respectively. For example, the color filters CF1, CF2, and CF3 may be disposed on the encapsulation layer ENC so as to correspond to the emission areas EA1, EA2, and EA3, respectively.

The color filters CF1, CF2, and CF3 may include the first color filter CF1, the second color filter CF2, and the third color filter CF3 disposed to each correspond to different emission areas EA1, EA2, and EA3. The color filters CF1, CF2, and CF3 may include colorants such as dyes or pigments absorbing light of wavelength bands other than light of a specific wavelength band, and may be disposed to correspond to colors of the light emitting from the emission areas EA1, EA2, and EA3. For example, the first color filter CF1 may be a red color filter disposed to overlap the first emission area EA1 and transmitting only the red light therethrough. The second color filter CF2 may be a green color filter disposed to overlap the second emission area EA2 and transmitting only the green light therethrough, and the third color filter CF3 may be a blue color filter disposed to overlap the third emission area EA3 and transmitting only the blue light therethrough.

The plurality of color filters CF1, CF2, and CF3 may be disposed to partially overlap other adjacent color filters CF1, CF2, and CF3. Different color filters CF1, CF2, and CF3 may overlap each other on the encapsulation layer ENC in areas that do not overlap the emission areas EA1, EA2, and EA3. In the display device 10, the color filters CF1, CF2, and CF3 are disposed to overlap each other, and accordingly, an intensity of reflected light by external light may be reduced. Furthermore, a color feeling of the reflected light by the external light may be controlled by adjusting an arrangement, shapes, areas, and the like, of the color filters CF1, CF2, and CF3 in plan view. However, the present disclosure is not limited thereto. The plurality of color filters CF1, CF2, and CF3 may be spaced apart from other adjacent color filters CF1, CF2, and CF3 on the encapsulation layer ENC.

Meanwhile, although not illustrated, the display device 10 according to an exemplary embodiment may further include a light blocking layer disposed between adjacent color filters (e.g., between the first color filter CF1 and the second color filter CF2 and between the second color filter CF2 and the third color filter CF3) on the encapsulation layer ENC. The light blocking layer may include a plurality of holes disposed to each overlap the emission areas EA1, EA2, and EA3. For example, a first hole may be disposed to overlap the first emission area EA1. A second hole may be disposed to overlap the second emission area EA2, and a third hole may be disposed to overlap the third emission area EA3. An area or a size of each of the holes of the light blocking layer may be greater than an area or a size of each of the emission areas EA1, EA2, and EA3 defined by the bank PDL. The holes of the light blocking layer are formed to be greater than the emission areas EA1, EA2, and EA3, and accordingly, the light emitted from the respective emission areas EA1, EA2, and EA3 may be viewed by a user not only from a front surface but also from side surfaces of the display device 10.

The light blocking layer may include a light absorbing material. For example, the light blocking layer may include an inorganic black pigment or an organic black pigment. The inorganic black pigment may be carbon black, and the organic black pigment may include at least one of lactam black, perylene black, and aniline black, but the present disclosure is not limited thereto. The light blocking layer may prevent color mixing due to permeation of visible light between the first to third emission areas EA1, EA2, and EA3 to improve a color gamut of the display device 10.

An overcoat layer OC may be disposed on the color filters CF1, CF2, and CF3 to planarize upper ends of the color filters CF1, CF2, and CF3. The overcoat layer OC may be a colorless light transmitting layer that does not have a color of a visible light band. For example, the overcoat layer OC may include a colorless light transmitting organic material such as an acrylic resin.

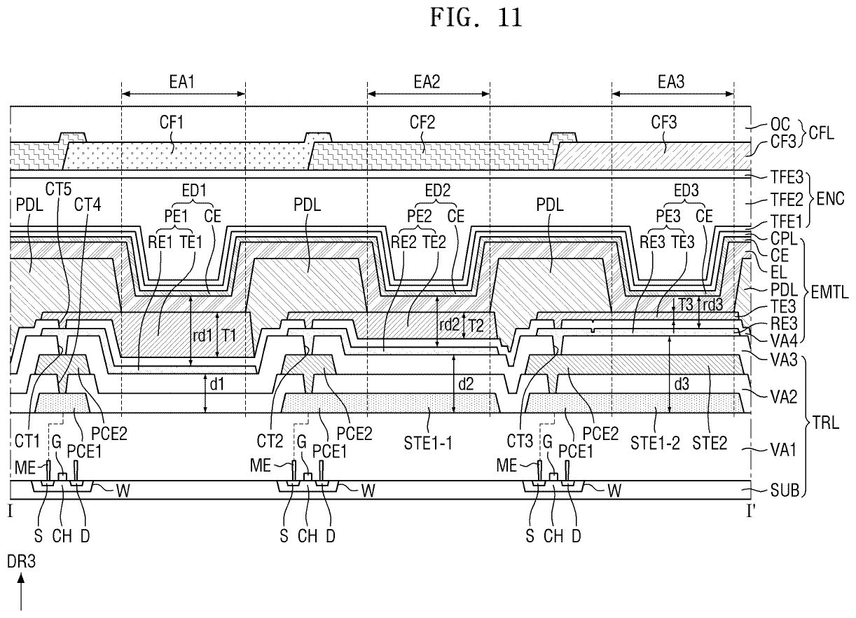

FIG. 11 is a cross-sectional view of a display device according to an exemplary embodiment taken along line I-I′ of FIG. 6.

A display device 10 of FIG. 11 is different from the display device 10 of FIG. 10 described above in a shape of at least one stepped electrode, and such a difference will be mainly described below.

As illustrated in FIG. 11, a first-first stepped electrode STE1-1 may be connected to a first pixel connection electrode PCE1 connected to the second pixel electrode PE2 (hereinafter referred to as a first pixel connection PCE1 of the second pixel PX2). In other words, the first-first stepped electrode STE1-1 may be connected to the first pixel connection electrode PCE1 of the second pixel PX2. Accordingly, the first-first stepped electrode STE1-1 may receive a voltage (hereinafter referred to as a pixel voltage) from a transistor of the second pixel PX2 through the first pixel connection electrode PCE1 of the second pixel PX2.

The first-first stepped electrode STE1-1 may be formed integrally with the first pixel connection electrode PCE1 of the second pixel PX2. In such a case, a structure including the first-first stepped electrode STE1-1 and the first pixel connection electrode PCE1 of the second pixel PX2 may correspond to, for example, a shape in which the first pixel connection electrode PCE1 of the second pixel PX2 further extends to the second emission area EA2.

A first-second stepped electrode STE1-2 may be formed integrally with a first pixel connection electrode PCE1 of the third pixel PX3. In such a case, a structure including the first-second stepped electrode STE1-2 and the first pixel connection electrode PCE1 of the third pixel PX3 may correspond to, for example, a shape in which the first pixel connection electrode PCE1 of the third pixel PX3 further extends to the third emission area EA3.

A second stepped electrode STE2 may be formed integrally with a second pixel connection electrode PCE2 of the third pixel PX3. In such a case, a structure including the second stepped electrode STE2 and the second pixel connection electrode PCE2 of the third pixel PX3 may correspond to, for example, a shape in which the second pixel connection electrode PCE2 of the third pixel PX3 further extends to the third emission area EA3.

The common voltage described above may not be applied to the first-first stepped electrode STE1-1 and the first-second stepped electrode STE1-2 in FIG. 11. For example, the first-first stepped electrode STE1-1 and the first-second stepped electrode STE1-2 in FIG. 11 may not be connected to the common voltage line VSL and/or the outer common voltage line EVSL. In other words, when any stepped electrode is connected to the pixel connection electrode, the stepped electrode is not connected to the power line described above.

The driving voltage described above may not be applied to the second stepped electrode STE2 in FIG. 11. For example, the second stepped electrode STE2 in FIG. 11 may not be connected to the driving voltage line VDL and/or the outer driving voltage line EVDL. In other words, when any stepped electrode is connected to the pixel connection electrode, the stepped electrode is not connected to the power line described above.

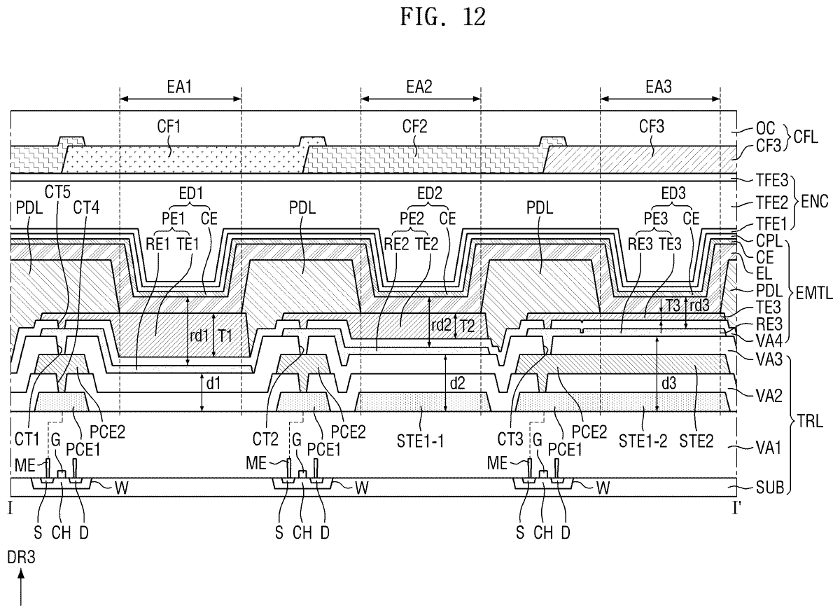

FIG. 12 is a cross-sectional view of a display device according to an exemplary embodiment taken along line I-I′ of FIG. 6.

A display device of FIG. 12 is different from the display device of FIG. 10 described above in a shape of at least one stepped electrode, and such a difference will be mainly described below.

As illustrated in FIG. 12, a first-first stepped electrode STE1-1 may have the same structure as the first-first stepped electrode STE1-1 of FIG. 10 described above.

In addition, as illustrated in FIG. 12, a first-second stepped electrode STE1-2 and a second stepped electrode STE2 may have the same structures as the first-second stepped electrode STE1-2 and the second stepped electrode STE2 of FIG. 11 described above, respectively.

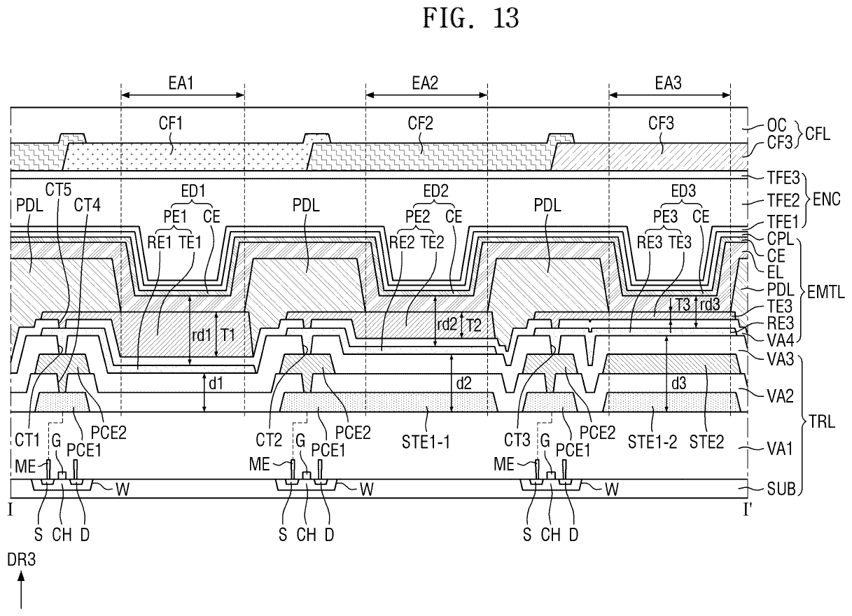

FIG. 13 is a cross-sectional view of a display device according to an exemplary embodiment taken along line I-I′ of FIG. 6.

A display device 10 of FIG. 13 is different from the display device 10 of FIG. 10 described above in a shape of at least one stepped electrode, and such a difference will be mainly described below.

As illustrated in FIG. 13, a first-first stepped electrode STE1-1 may have the same structure as the first-first stepped electrode STE1-1 of FIG. 11 described above.

In addition, as illustrated in FIG. 13, a first-second stepped electrode STE1-2 and a second stepped electrode STE2 may have the same structures as the first-second stepped electrode STE1-2 and the second stepped electrode STE2 of FIG. 10 described above, respectively.

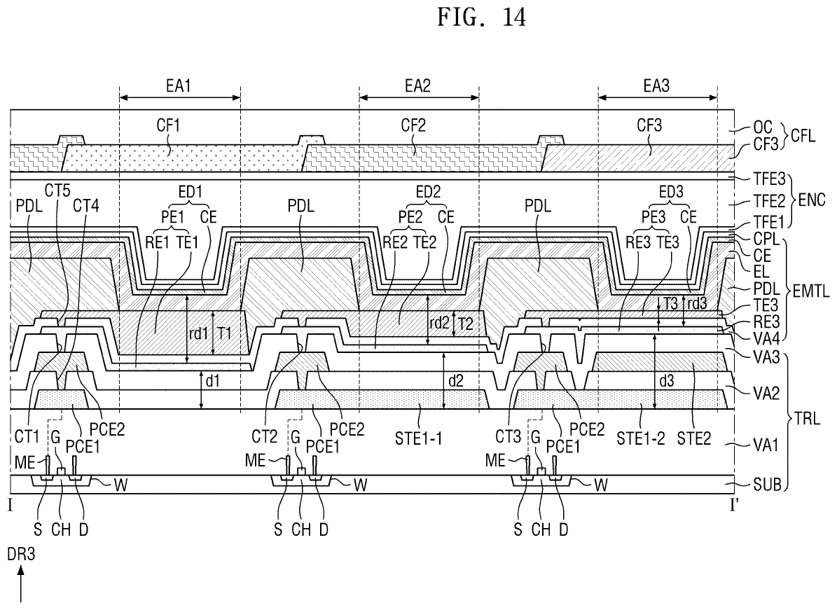

FIG. 14 is a cross-sectional view of a display device according to an exemplary embodiment taken along line I-I′ of FIG. 6.

A display device 10 of FIG. 14 is different from the display device 10 of FIG. 10 described above in a shape of at least one stepped electrode, and such a difference will be mainly described below.

As illustrated in FIG. 14, a first-first stepped electrode STE1-1 and a first-second stepped electrode STE1-2 may have the same structures as the first-first stepped electrode STE1-1 and the first-second stepped electrode STE1-2 of FIG. 11 described above, respectively.

In addition, as illustrated in FIG. 14, a second stepped electrode STE2 may have the same structure as the second stepped electrode STE2 of FIG. 10 described above.

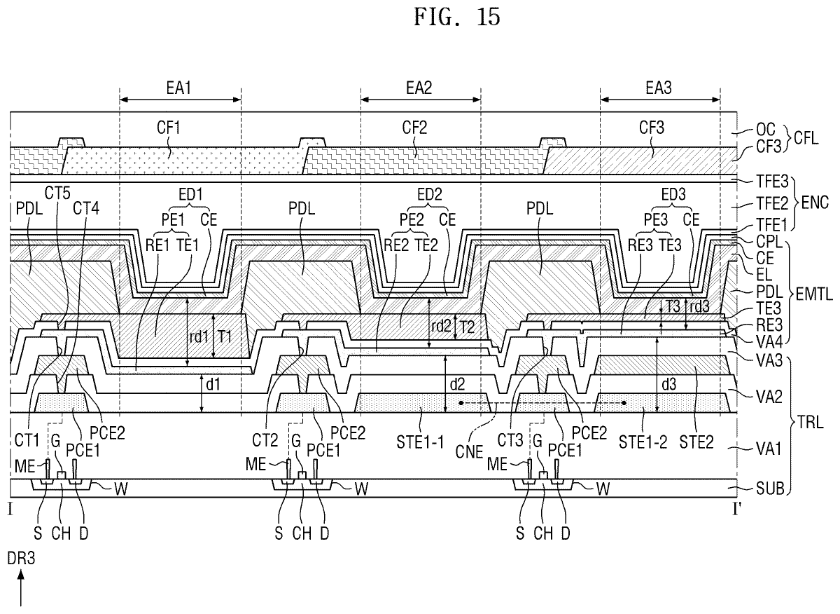

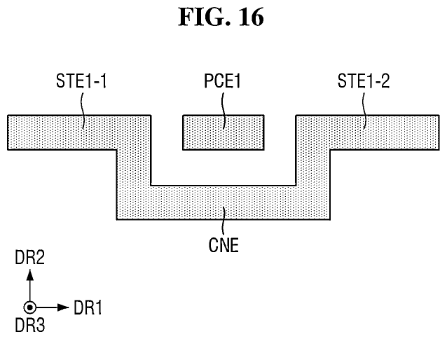

FIG. 15 is a cross-sectional view of a display device according to an exemplary embodiment taken along line I-I′ of FIG. 6. FIG. 16 is a plan view of a first-first stepped electrode STE1-1, a first pixel connection electrode PCE1, and a first-second stepped electrode STE1-2 of FIG. 15.

A display device 10 of FIG. 15 is different from the display device 10 of FIG. 10 described above in a shape of at least one stepped electrode, and such a difference will be mainly described below.

As illustrated in FIG. 15, the first-first stepped electrode STE1-1 and the first-second stepped electrode STE1-2 may be connected to each other. For example, as illustrated in FIG. 16, the first-first stepped electrode STE1-1 and the first-second stepped electrode STE1-2 may be formed integrally with each other. In this case, a connection electrode CNE connecting the first-first stepped electrode STE1-1 and the first-second stepped electrode STE1-2 to each other may connect the first-first stepped electrode STE1-1 and the first-second stepped electrode STE1-2 to each other while bypassing the first pixel connection electrode PCE1 disposed between the first-first stepped electrode STE1-1 and the first-second stepped electrode STE1-2 so as not to be short-circuited with the first pixel connection electrode PCE1, for example. As an example, the connection electrode CNE may have a curved shape in which it surrounds a portion of the first pixel connection electrode PCE1 of the third pixel PX3. For example, the connection electrode CNE may have a U-shape.

The first-first stepped electrode STE1-1, the connection electrode CNE, and the first-second stepped electrode STE1-2 of FIGS. 15 and 16 may be formed integrally with each other.

A structure including the first-first stepped electrode STE1-1, the connection electrode CNE, and the first-second stepped electrode STE1-2 of FIGS. 15 and 16 may be connected to, for example, the common voltage line VSL and/or the outer common voltage line EVSL described above.

A second stepped electrode STE2 of FIG. 15 may have the same structure as the second stepped electrode STE2 of FIG. 10 described above.

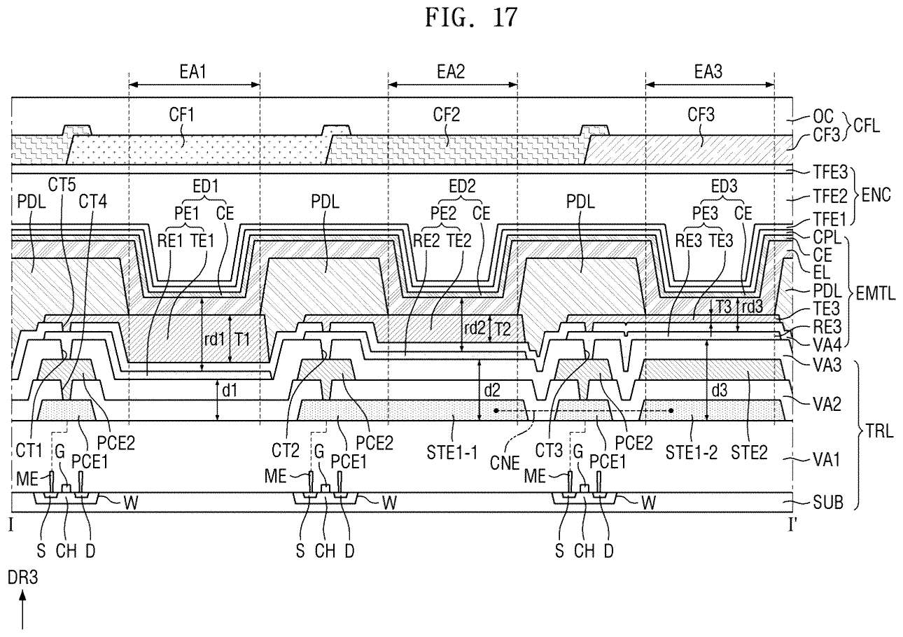

FIG. 17 is a cross-sectional view of a display device according to an exemplary embodiment taken along line I-I′ of FIG. 6.

A display device 10 of FIG. 17 is different from the display device 10 of FIG. 10 described above in a shape of at least one stepped electrode, and such a difference will be mainly described below.

As illustrated in FIG. 17, a first-first stepped electrode STE1-1 and a first-second stepped electrode STE1-2 may be connected to each other by the connection electrode CNE as illustrated in FIGS. 15 and 16.

In addition, as illustrated in FIG. 17, the first-first stepped electrode STE1-1 may be formed integrally with the first pixel connection electrode PCE1 of the second pixel PX2.

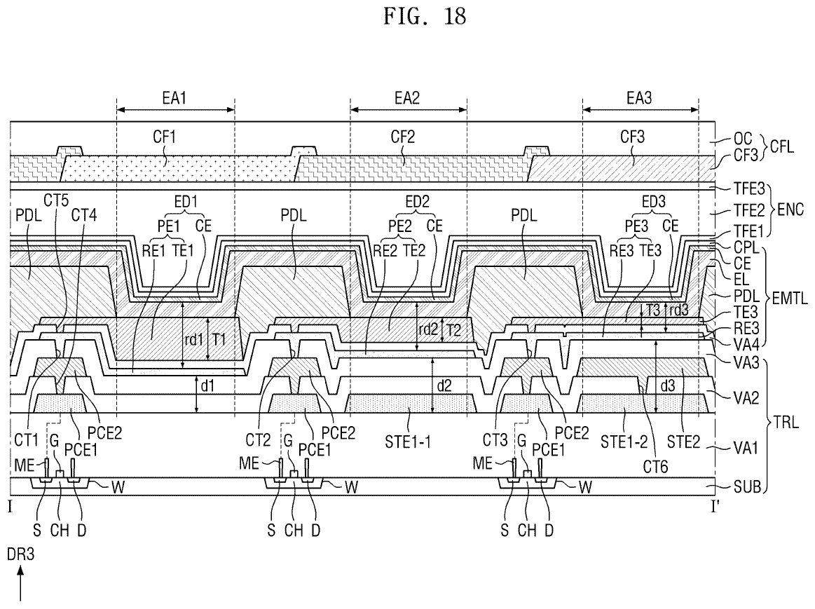

FIG. 18 is a cross-sectional view of a display device according to an exemplary embodiment taken along line I-I′ of FIG. 6.

A display device 10 of FIG. 18 is different from the display device 10 of FIG. 10 described above in a shape of at least one stepped electrode, and such a difference will be mainly described below.

A first-first stepped electrode STE1-1 of FIG. 18 may have the same structure as the first-first stepped electrode STE1-1 of FIG. 10 described above.

As illustrated in FIG. 18, a first-second stepped electrode STE1-2 and a second stepped electrode STE2 may be connected to each other. For example, the second stepped electrode STE2 may be connected to the first-second stepped electrode STE1-2 through a sixth contact hole CT6 penetrating through the second interlayer insulating film VA2.

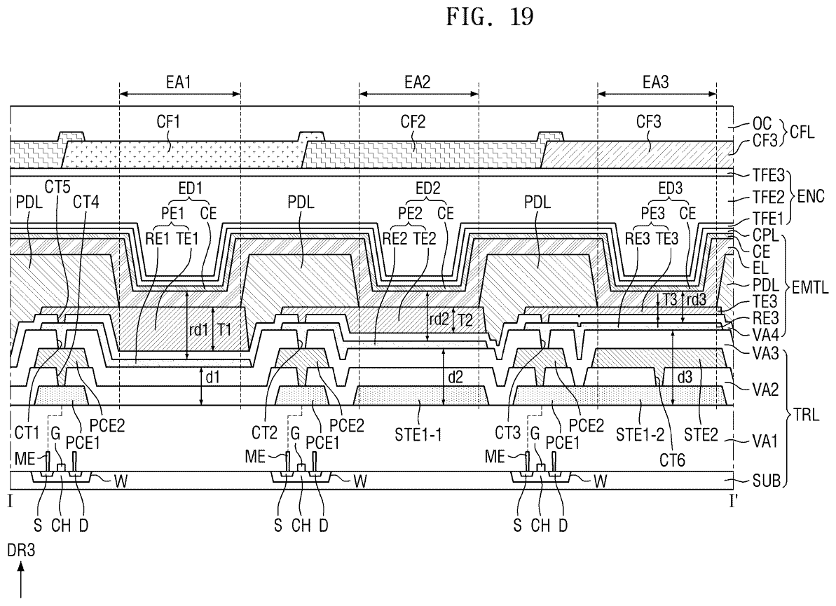

FIG. 19 is a cross-sectional view of a display device according to an exemplary embodiment taken along line I-I′ of FIG. 6.

A display device 10 of FIG. 19 is different from the display device 10 of FIG. 10 described above in a shape of at least one stepped electrode, and such a difference will be mainly described below.

A first-first stepped electrode STE1-1 of FIG. 19 may have the same structure as the first-first stepped electrode STE1-1 of FIG. 10 described above.

As illustrated in FIG. 19, a first-second stepped electrode STE1-2 and a second stepped electrode STE2 may be connected to each other. For example, the second stepped electrode STE2 may be connected to the first-second stepped electrode STE1-2 through a sixth contact hole CT6 penetrating through the second interlayer insulating film VA2. In this case, the first-second stepped electrode STE1-2 may be formed integrally with a first pixel connection electrode PCE1 of the third pixel PX3.

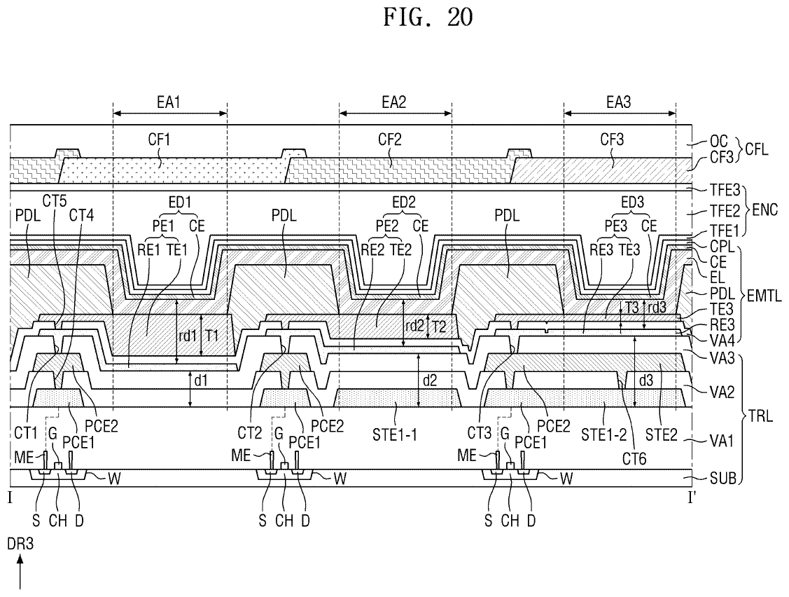

FIG. 20 is a cross-sectional view of a display device according to an exemplary embodiment taken along line I-I′ of FIG. 6.

A display device 10 of FIG. 20 is different from the display device 10 of FIG. 10 described above in a shape of at least one stepped electrode, and such a difference will be mainly described below.

A first-first stepped electrode STE1-1 of FIG. 20 may have the same structure as the first-first stepped electrode STE1-1 of FIG. 10 described above.

As illustrated in FIG. 20, a first-second stepped electrode STE1-2 and a second stepped electrode STE2 may be connected to each other. For example, the second stepped electrode STE2 may be connected to the first-second stepped electrode STE1-2 through a sixth contact hole CT6 penetrating through the second interlayer insulating film VA2. In this case, the first-second stepped electrode STE1-2 may be formed integrally with a first pixel connection electrode PCE1 of the third pixel PX3, and the second stepped electrode STE2 may be formed integrally with a second pixel connection electrode PCE2 of the third pixel PX3.

Meanwhile, other structures of the light emitting elements (e.g., ED1, ED2, and ED3 of FIG. 10) will be described below with reference to FIGS. 21 to 27.

FIG. 21 is a cross-sectional view illustrating a structure of a display element according to an exemplary embodiment. FIGS. 22 to 25 are cross-sectional views illustrating a structure of a light emitting element according to an exemplary embodiment.

Referring to FIG. 21, a light emitting element (e.g., an organic light emitting diode) according to an exemplary embodiment may include a pixel electrode 201, a common electrode 205, and a light providing layer 203 between the pixel electrode 201 and the common electrode 205 described above. Here, the pixel electrode 201 may be one of the first pixel electrode PE1, second pixel electrode PE2, and third pixel electrode PE3 described above. In addition, the common electrode 205 may be the common electrode CE described above. In addition, the light providing layer 203 may be the light providing layer EL described above. In this case, the pixel electrode 201 may include the reflective electrode and the light-transmitting electrode described above.

The pixel electrode 201 may include a light-transmitting conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 201 may be a reflective layer including silver (Ag), magnesium (Mg), aluminum (Al), platinum (Pt), palladium (Pd), gold (Au), nickel (Ni), neodymium (Nd), iridium (Ir), chromium (Cr), or compounds thereof. For example, the pixel electrode 201 may have a three-layer structure of ITO/Ag/ITO.

The common electrode 205 may be disposed on the light providing layer 203. The common electrode 205 may include a metal having a low work function, an alloy, an electrically conductive compound, or any combination thereof. For example, the common electrode 205 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The common electrode 205 may be a transmissive electrode, a semi-transmissive electrode, or a reflective electrode.

The light providing layer 203 may include a high molecular or low molecular organic material emitting light of a predetermined color. The light providing layer 203 may further include a metal-containing compound such as an organometallic compound, an inorganic material such as quantum dots, and the like, in addition to various organic materials.

In an exemplary embodiment, the light providing layer 203 may include one light emitting layer and a first functional layer and a second functional layer respective disposed below and above the one light emitting layer. The first functional layer may include, for example, a hole transport layer (HTL) or a hole transport layer and a hole injection layer (HIL). The second functional layer is a component disposed on the light emitting layer and is optional. For example, the light providing layer 203 may or may not include the second functional layer. The second functional layer may include an electron transport layer (ETL) and/or an electron injection layer (EIL).

In an exemplary embodiment, the light providing layer 203 may include two or more light emitting units sequentially stacked between the pixel electrode 201 and the common electrode 205 and a charge generation layer CGL disposed between the two light emitting units. When the light providing layer 203 includes the light emitting units and the charge generation layer, the light emitting element (e.g., the organic light emitting diode) may be a tandem light emitting element. The light emitting element (e.g., the organic light emitting diode) may improve color purity and luminous efficiency by having a stacked structure of a plurality of light emitting units.

One light emitting unit may include a light emitting layer and a first functional layer and a second functional layer respective disposed below and above the light emitting layer. The charge generation layer CGL may include a negative charge generation layer and a positive charge generation layer. The luminous efficiency of the organic light emitting diode, which is the tandem light emitting element having a plurality of light emitting layers, may be further increased by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

In an exemplary embodiment, as illustrated in FIG. 22, the light emitting element (e.g., the organic light emitting diode) may include a first light emitting unit EU1 including a first light emitting layer EL1 and a second light emitting layer EU2 including a second light emitting layer EL2 that are sequentially stacked. A charge generation layer CGL may be disposed between the first light emitting unit EU1 and the second light emitting unit EU2. For example, the light emitting element (e.g., the organic light emitting diode) may include the pixel electrode 201, the first light emitting layer EL1, the charge generation layer CGL, the second light emitting layer EL2, and the common electrode 205 that are sequentially stacked. A first functional layer and a second functional layer may be disposed below and above the first light emitting layer EL1, respectively. A first functional layer and a second functional layer may be disposed below and above the second light emitting layer EL2, respectively. The first light emitting layer EL1 may be a blue light emitting layer, and the second light emitting layer EL2 may be a yellow light emitting layer.

In an exemplary embodiment, as illustrated in FIG. 23, the light emitting element (e.g., the organic light emitting diode) may include a first light emitting unit EU1 including a first light emitting layer EL1, a third light emitting unit EU3 including a first light emitting layer EL1, and a second light emitting layer EU2 including a second light emitting layer EL2. A first charge generation layer CGL1 may be disposed between the first light emitting unit EU1 and the second light emitting unit EU2, and a second charge generation layer CGL2 may be disposed between the second light emitting unit EU2 and the third light emitting unit EU3. For example, the light emitting element (e.g., the organic light emitting diode) may include the pixel electrode 201, the first light emitting layer EL1, the first charge generation layer CGL1, the second light emitting layer EL2, the second charge generation layer CGL2, the first light emitting layer EL1, and the common electrode 205 that are sequentially stacked. A first functional layer and a second functional layer may be disposed below and above the first light emitting layer EL1, respectively. A first functional layer and a second functional layer may be disposed below and above the second light emitting layer EL2, respectively. The first light emitting layer EL1 may be a blue light emitting layer, and the second light emitting layer EL2 may be a yellow light emitting layer.

In an exemplary embodiment, in the light emitting element (e.g., the organic light emitting diode), the second light emitting unit EU2 may further include a third light emitting layer EL3 and/or a fourth light emitting layer EL4 in direct contact with the second light emitting layer EL2 below and/or above the second light emitting layer EL2 in addition to the second light emitting layer EL2. Here, the phrase “direct contact” may mean that no other layer is disposed between the second light emitting layer EL2 and the third light emitting layer EL3 and/or between the second light emitting layer EL2 and the fourth light emitting layer EL4. The third light emitting layer EL3 may be a red light emitting layer, and the fourth light emitting layer EL4 may be a green light emitting layer.

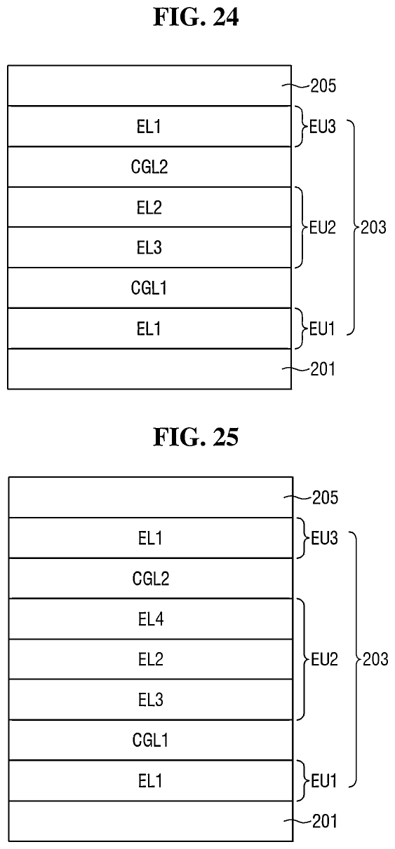

For example, as illustrated in FIG. 24, the light emitting element (e.g., the organic light emitting diode) may include the pixel electrode 201, the first light emitting layer EL1, the first charge generation layer CGL1, the third light emitting layer EL3, the second light emitting layer EL2, the second charge generation layer CGL2, the first light emitting layer EL1, and the common electrode 205 that are sequentially stacked. Alternatively, as illustrated in FIG. 25, the light emitting element (e.g., the organic light emitting diode) may include the pixel electrode 201, the first light emitting layer EL1, the first charge generation layer CGL1, the third light emitting layer EL3, the second light emitting layer EL2, the fourth light emitting layer EL4, the second charge generation layer CGL2, the first light emitting layer EL1, and the common electrode 205 that are sequentially stacked.

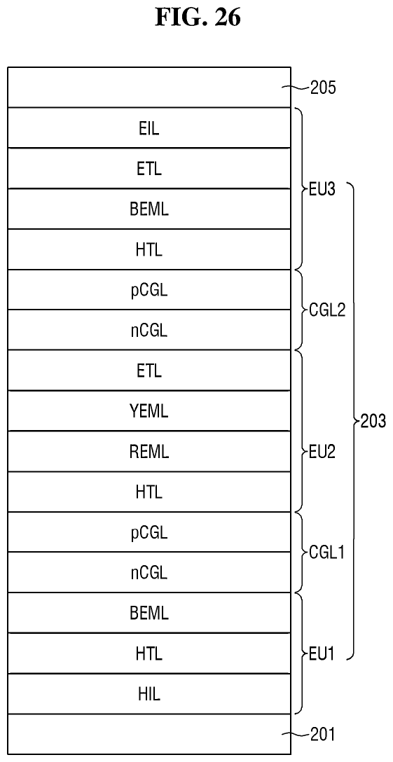

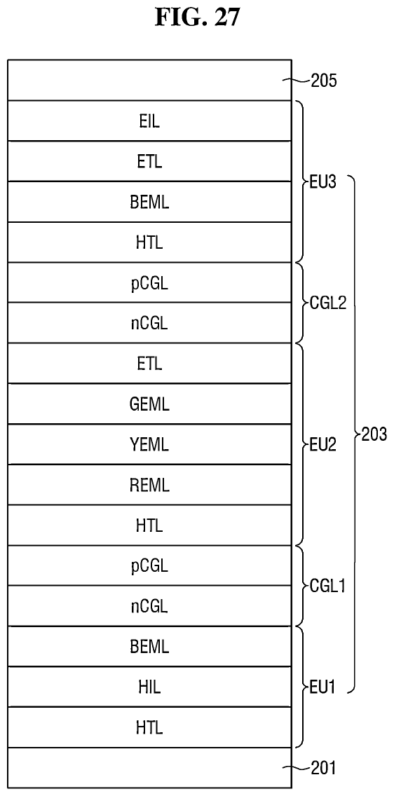

FIG. 26 is a cross-sectional view illustrating an example of an organic light emitting diode of FIG. 24. FIG. 27 is a cross-sectional view illustrating an example of an organic light emitting diode of FIG. 25.

Referring to FIG. 26, the light emitting element (e.g., the organic light emitting diode) may include a first light emitting unit EU1, a second light emitting unit EU2, and a third light emitting unit EU3 that are sequentially stacked. A first charge generation layer CGL1 may be disposed between the first light emitting unit EU1 and the second light emitting unit EU2, and a second charge generation layer CGL2 may be disposed between the second light emitting unit EU2 and the third light emitting unit EU3. Each of the first charge generation layer CGL1 and the second charge generation layer CGL2 may include a negative charge generation layer nCGL and a positive charge generation layer pCGL. The first light emitting unit EU1 may include a blue light emitting layer BEML.

The first light emitting unit EU1 may further include a hole injection layer HIL and a hole transport layer HTL between the pixel electrode 201 and the blue light emitting layer BEML. In an exemplary embodiment, a p-doped layer may be further included between the hole injection layer HIL and the hole transport layer HTL. The p-doped layer may be formed by doping the hole injection layer HIL with a p-type doping material. In an exemplary embodiment, at least one of a blue light auxiliary layer, an electron blocking layer, and a buffer layer may be further included between the blue light emitting layer BEML and the hole transport layer HTL. The blue light auxiliary layer may increase emission efficiency of the blue light emitting layer BEML. The blue light auxiliary layer may increase emission efficiency of the blue light emitting layer BEML by adjusting hole charge balance. The electron blocking layer may prevent injection of electrons into the hole transport layer HTL. The buffer layer may compensate for a resonance distance according to a wavelength of light emitted from the light emitting layer.

The second light emitting unit EU2 may include a yellow light emitting layer YEML and a red light emitting layer REML in direct contact with the yellow light emitting layer YEML below the yellow light emitting layer YEML. The second light emitting unit EU2 may further include a hole transport layer HTL between the positive charge generation layer pCGL of the first charge generation layer CGL1 and the red light emitting layer REML, and may further include an electron transport layer ETL between the yellow light emitting layer YEML and the negative charge generation layer nCGL of the second charge generation layer CGL2.

The third light emitting unit EU3 may include a blue light emitting layer BEML. The third light emitting unit EU3 may further include a hole transport layer HTL between the positive charge generation layer pCGL of the second charge generation layer CGL2 and the blue light emitting layer BEML. The third light emitting unit EU3 may further include an electron transport layer ETL and an electron injection layer EIL between the blue light emitting layer BEML and the common electrode 205. The electron transport layer ETL may be a single layer or multiple layers. In an exemplary embodiment, at least one of a blue light auxiliary layer, an electron blocking layer, and a buffer layer may be further included between the blue light emitting layer BEML and the hole transport layer HTL. At least one of a hole blocking layer and a buffer layer may be further included between the blue light emitting layer BEML and the electron transport layer ETL. The hole blocking layer may prevent injection of holes into the electron transport layer ETL.

The light emitting element (e.g., the organic light emitting diode) illustrated in FIG. 27 is different from the light emitting element (e.g., the organic light emitting diode) illustrated in FIG. 26 in a stacked structure of the second light emitting unit EU2, and is the same as the light emitting element (e.g., the organic light emitting diode) illustrated in FIG. 26 in other configurations. Referring to FIG. 27, the second light emitting unit EU2 may include a yellow light emitting layer YEML, a red light emitting layer REML in direct contact with the yellow light emitting layer YEML below the yellow light emitting layer YEML, and a green light emitting layer GEML in direct contact with the yellow light emitting layer YEML above the yellow light emitting layer YEML. The second light emitting unit EU2 may further include a hole transport layer HTL between the positive charge generation layer pCGL of the first charge generation layer CGL1 and the red light emitting layer REML, and may further include an electron transport layer ETL between the green light emitting layer GEML and the negative charge generation layer nCGL of the second charge generation layer CGL2.

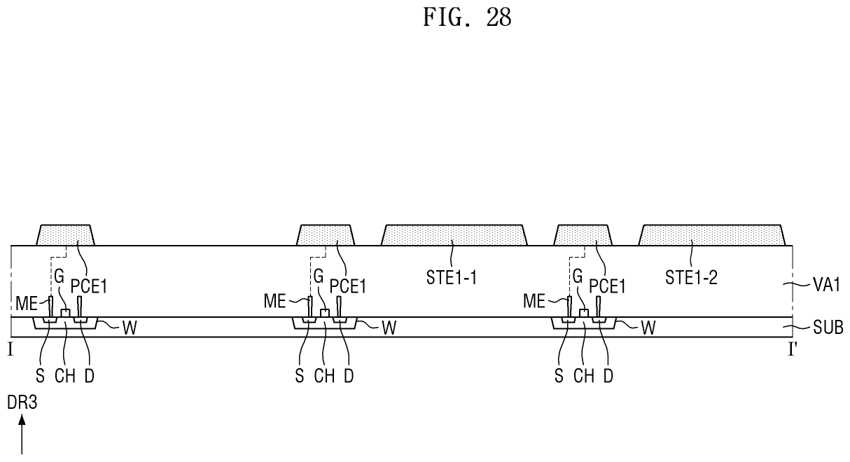

FIGS. 28 to 36 are cross-sectional views for describing processes of a manufacturing method of the display device according to an exemplary embodiment.

First, as illustrated in FIG. 28, a substrate SUB on which a first interlayer insulating film VA1 is formed may be prepared. Thereafter, first pixel connection electrodes PCE1, a first-first stepped electrode STE1-1, and a first-second stepped electrode STE1-2 may be formed on the first interlayer insulating film VAL. The first pixel connection electrodes PCE1, the first-first stepped electrode STE1-1, and the first-second stepped electrode STE1-2 may be simultaneously formed using the same material.

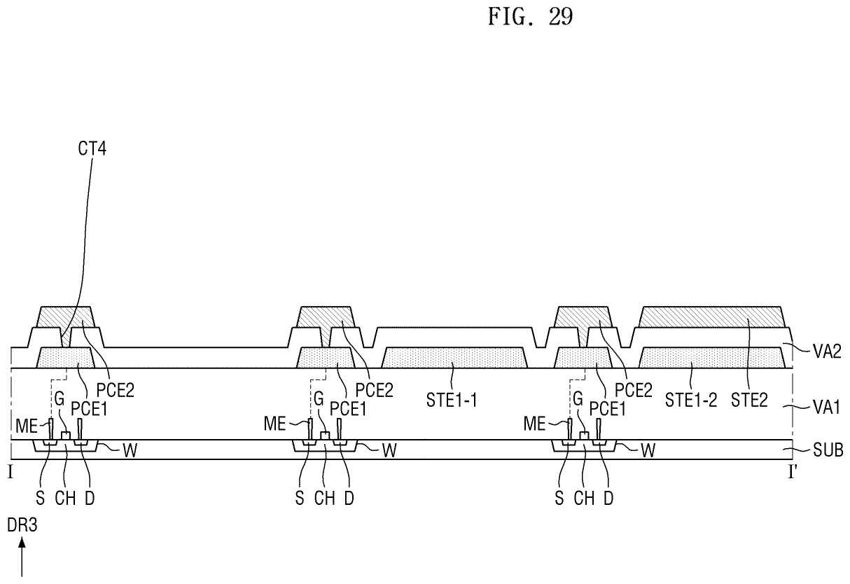

Thereafter, as illustrated in FIG. 29, a second interlayer insulating film VA2 may be formed on the entire surface of the substrate SUB including the first pixel connection electrodes PCE1, the first-first stepped electrode STE1-1, and the first-second stepped electrode STE1-2. Next, fourth contact holes CT4 penetrating through the second interlayer insulating film VA2 may be formed. The first pixel connection electrodes PCE1 of the respective pixels PX1, PX2, and PX3 may be exposed by the fourth contact holes CT4 of the second interlayer insulating film VA2. Subsequently, second pixel connection electrodes PCE2 and a second stepped electrode STE2 may be formed on the second interlayer insulating film VA2. The second pixel connection electrodes PCE2 and the second stepped electrode STE2 may be simultaneously formed using the same material. In this case, the second pixel connection electrodes PCE2 may be connected to the first pixel connection electrodes PCE1 through the fourth contact holes CT4.

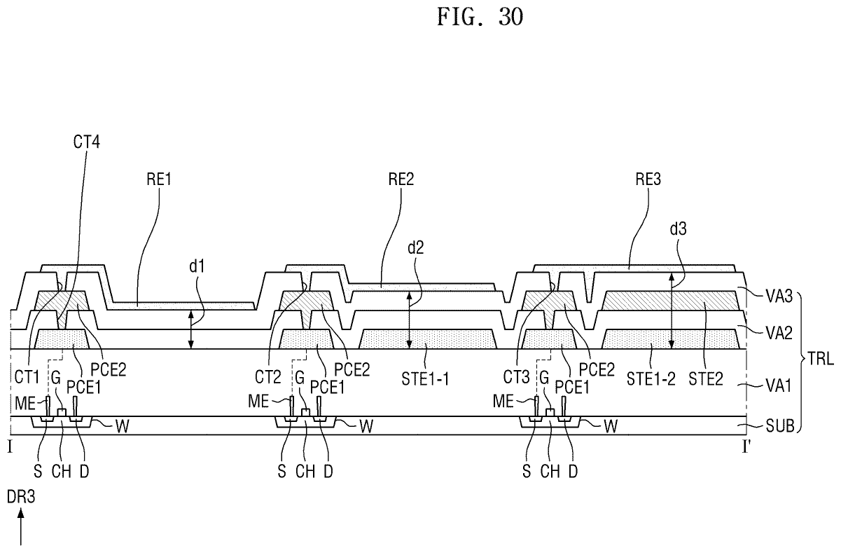

Next, as illustrated in FIG. 30, a third interlayer insulating film VA3 may be formed on the entire surface of the substrate SUB including the second pixel connection electrodes PCE2 and the second stepped electrode STE2. Thereafter, a first contact hole CT1, a second contact hole CT2, and a third contact hole CT3 penetrating through the third interlayer insulating film VA3 may be formed. The second pixel connection electrode PCE2 of the first pixel PX1 may be exposed by the first contact hole CT1 of the third interlayer insulating film VA3, the second pixel connection electrode PCE2 of the second pixel PX2 may be exposed by the second contact hole CT2 of the third interlayer insulating film VA3, and the second pixel connection electrode PCE2 of the third pixel PX3 may be exposed by the third contact hole CT3 of the third interlayer insulating film VA3. Subsequently, a first reflective electrode RE1, a second reflective electrode RE2, and a third reflective electrode RE3 may be formed on the third interlayer insulating film VA3. The first reflective electrode RE1, the second reflective electrode RE2, and the third reflective electrode RE3 may be simultaneously formed using the same material. In this case, the first reflective electrode RE1 may be connected to the second pixel connection electrode PCE2 of the first pixel PX1 through the first contact hole CT1 of the third interlayer insulating film VA3, the second reflective electrode RE2 may be connected to the second pixel connection electrode PCE2 of the second pixel PX2 through the second contact hole CT2 of the third interlayer insulating film VA3, and the third reflective electrode RE3 may be connected to the second pixel connection electrode PCE2 of the third pixel PX3 through the third contact hole CT3 of the third interlayer insulating film VA3.

Meanwhile, as illustrated in FIG. 30, a stepped electrode overlapping the first reflective electrode RE1 may not exist between the first reflective electrode RE1 and the first interlayer insulating film VA1 (e.g., the uppermost insulating film of the first interlayer insulating film VA1), one stepped electrode STE1-1 overlapping the second reflective electrode RE2 in the third direction DR3 may exist between the second reflective electrode RE2 and the first interlayer insulating film VA1 (e.g., the uppermost insulating film of the first interlayer insulating film VA1), and two stepped electrodes STE1-2 and STE2 overlapping the third reflective electrode RE3 in the third direction DR3 may exist between the third reflective electrode RE3 and the first interlayer insulating film VA1 (e.g., the uppermost insulating film of the first interlayer insulating film VA1).

Since the numbers of stacked stepped electrodes disposed below the respective reflective electrodes RE1, RE2, and RE3 are different from each other as described above, distances between the first interlayer insulating film VA1 (e.g., the uppermost insulating film of the first interlayer insulating film VA1) and the respective reflective electrodes RE1, RE2, and RE3 may be different from each other. For example, as illustrated in FIG. 30, a distance d1 between the first interlayer insulating film VA1 (e.g., the uppermost insulating film of the first interlayer insulating film VA1) and the first reflective electrode RE1, a distance d2 between the first interlayer insulating film VA1 (e.g., the uppermost insulating film of the first interlayer insulating film VA1) and the second reflective electrode RE2, and a distance d3 between the first interlayer insulating film VA1 (e.g., the uppermost insulating film of the first interlayer insulating film VA1) and the third reflective electrode RE3 may be different from each other.

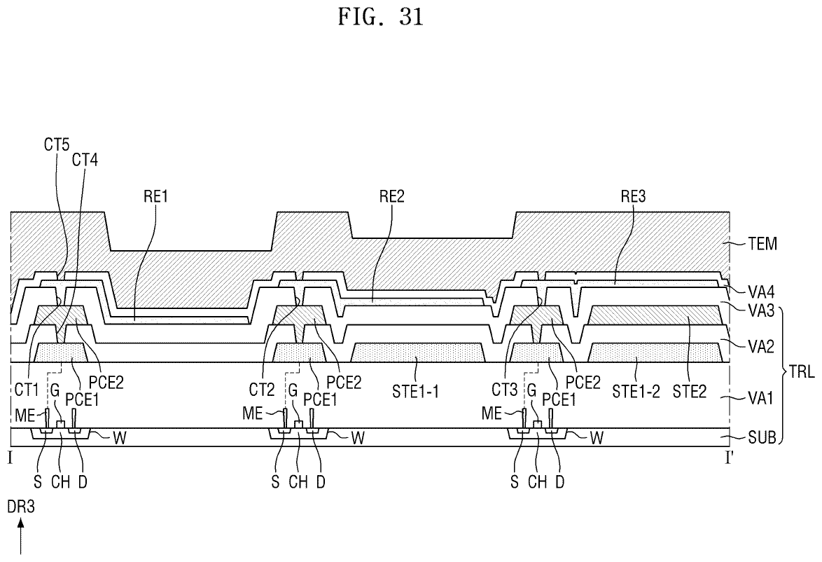

Next, as illustrated in FIG. 31, a fourth interlayer insulating film VA4 may be formed on the entire surface of the substrate SUB including the first reflective electrode RE1, the second reflective electrode RE2, and the third reflective electrode RE3. Thereafter, fifth contact holes CT5 penetrating through the fourth interlayer insulating film VA4 may be formed. The fifth contact holes CT5 may expose the first reflective electrode RE1, the second reflective electrode RE2, and the third reflective electrode RE3, respectively. Next, a light-transmitting material layer TEM may be formed on the entire surface of the substrate SUB including the fourth interlayer insulating film VA4. The light-transmitting material layer TEM may be in contact with the first reflective electrode RE1, the second reflective electrode RE2, and the third reflective electrode RE3 through the fifth contact holes CT5. At this time, the light-transmitting material layer TEM may have a step due to patterns disposed therebelow (e.g., the first-first stepped electrode STE1-1, the first-second stepped electrode STE1-2, and the second stepped electrode STE2).

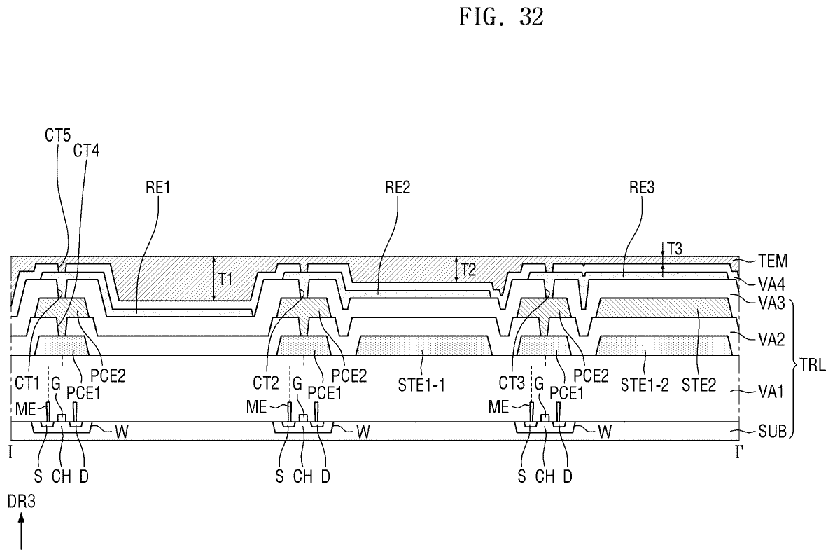

Thereafter, as illustrated in FIG. 32, the light-transmitting material layer TEM may be planarized. This planarization process may be performed based on the lowest stepped portion of the light-transmitting material layer TEM. Meanwhile, the above-described planarization process may be performed by chemical mechanical polishing (CMP). By this planarization process, as in an example illustrated in FIG. 32, an upper surface of the light-transmitting material layer TEM may be substantially parallel to a lower surface of the substrate SUB. Accordingly, a thickness T1 of the light-transmitting material layer TEM overlapping the first reflective electrode RE1 in the first emission area EA1, a thickness T2 of the light-transmitting material layer TEM overlapping the second reflective electrode RE2 in the second emission area EA2, and a thickness T3 of the light-transmitting material layer TEM overlapping the third reflective electrode RE3 in the third emission area EA3 may be different from each other.

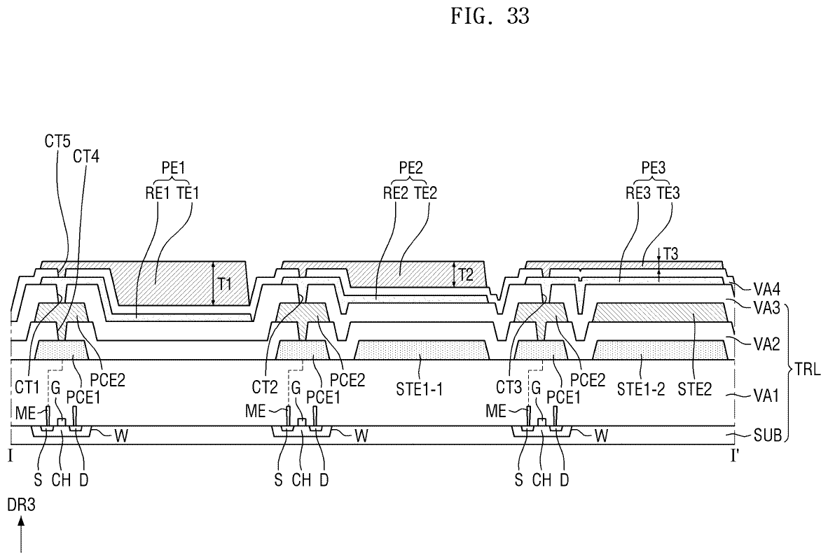

Subsequently, as illustrated in FIG. 33, the light-transmitting material layer TEM may be patterned through photolithography and etching processes. By patterning the light-transmitting material layer TEM, a first light-transmitting electrode TE1, a second light-transmitting electrode TE2, and a third light-transmitting electrode TE3 separated from each other may be formed on the fourth interlayer insulating film VA4. The first light-transmitting electrode TE1 may be connected to the first reflective electrode RE1 through the fifth contact hole CT5 of the fourth interlayer insulating film VA4, the second light-transmitting electrode TE2 may be connected to the second reflective electrode RE2 through the fifth contact hole CT5 of the fourth interlayer insulating film VA4, and the third light-transmitting electrode TE3 may be connected to the third reflective electrode RE3 through the fifth contact hole CT5 of the fourth interlayer insulating film VA4. Accordingly, a first pixel electrode PE1 including the first light-transmitting electrode TE1 and the first reflective electrode RE1, a second pixel PE2 including the second light-transmitting electrode TE2 and the second reflective electrode RE2, and a third pixel electrode PE3 including the third light-transmitting electrode TE3 and the third reflective electrode RE3 may be formed.

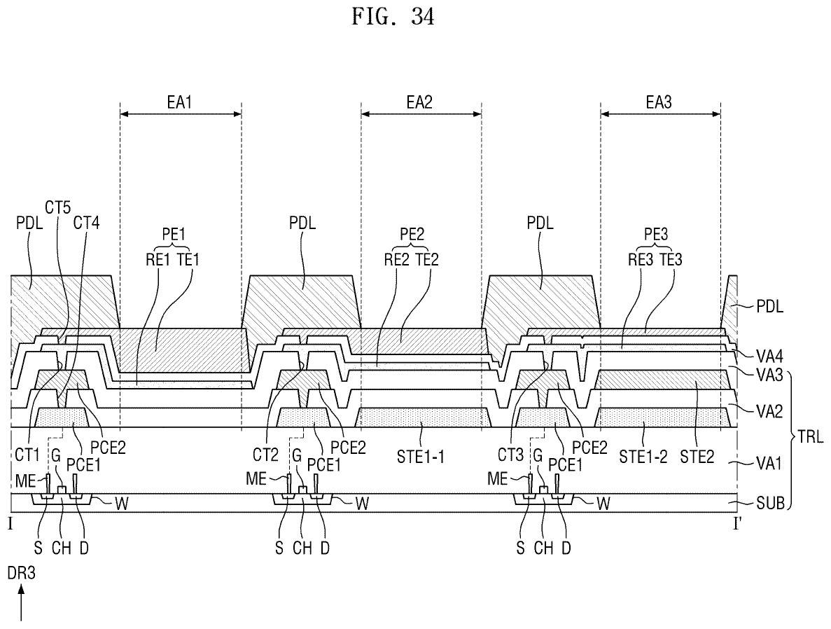

Thereafter, as illustrated in FIG. 34, a bank PDL defining the first emission area EA1, the second emission area EA2, and the third emission area EA3 may be formed on the first light-transmitting electrode TE1, the second light-transmitting electrode TE2, and the third light-transmitting electrode TE3.

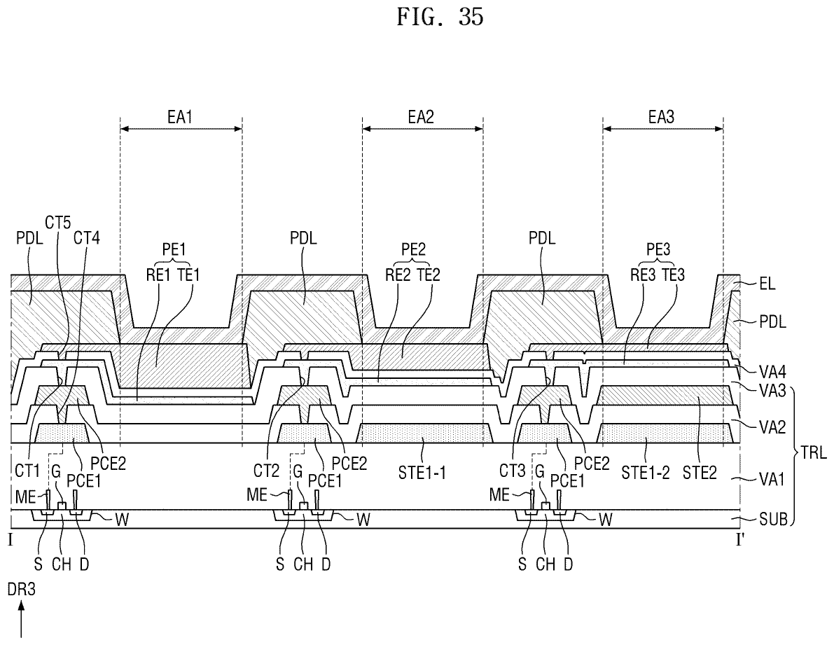

Subsequently, as illustrated in FIG. 35, a light providing layer EL may be formed on the first reflective electrode RE1, the second reflective electrode RE2, the third reflective electrode RE3, and the bank PDL.

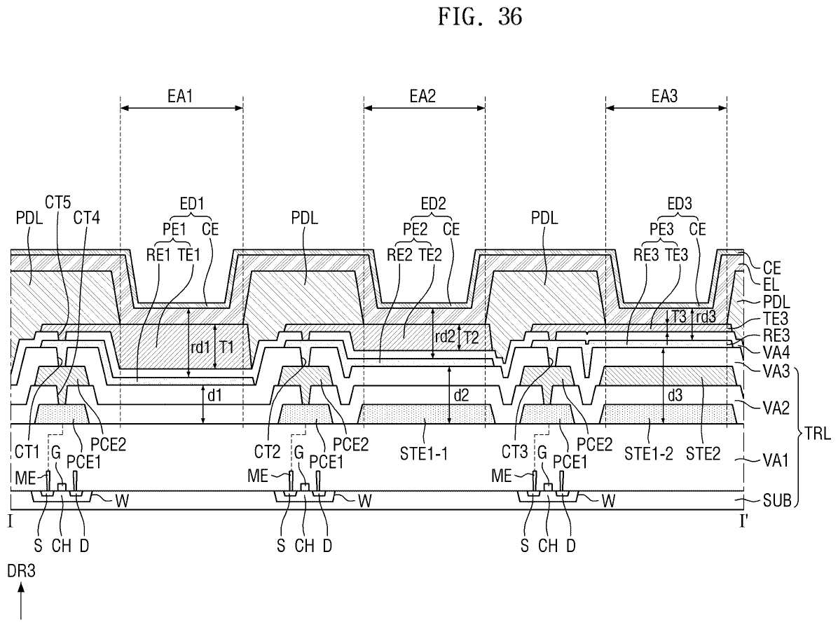

Next, as illustrated in FIG. 36, a common electrode CE may be formed on the light providing layer EL. In this case, arrangement heights of the first reflective electrode RE1, the second reflective electrode RE2, and the third reflective electrode RE3 are different from each other by the stepped electrodes STE1-1, STE1-2, and STE2 described above, whereas upper surfaces of the first light-transmitting electrode TE1, the second light-transmitting electrode TE2, and the third light-transmitting electrode TE3 are disposed at the same height by the above-described planarization process of the light-transmitting material layer TEM. Thus, a resonance distance rd1 between the common electrode CE and the first reflective electrode RE1, a resonance distance rd2 between the common electrode CE and the second reflective electrode RE2, and a resonance distance rd3 between the common electrode CE and the third reflective electrode RE3 may be different from each other.

Meanwhile, although not illustrated, the display device 10 may be manufactured by forming the above-described capping layer CPL, encapsulation layer ENC, and color filter layer CFL.

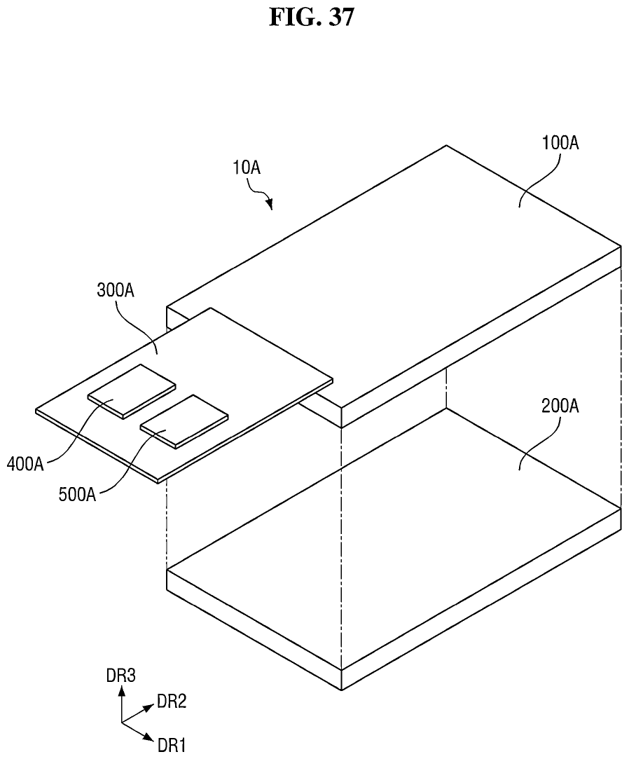

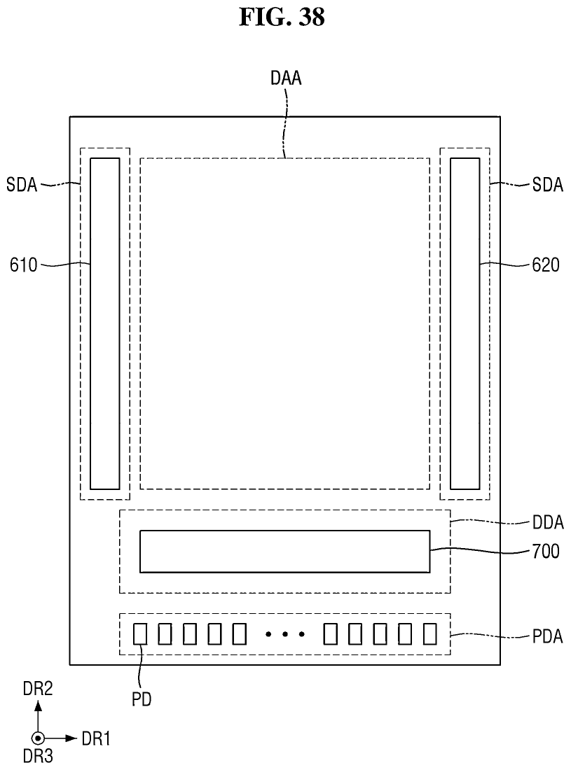

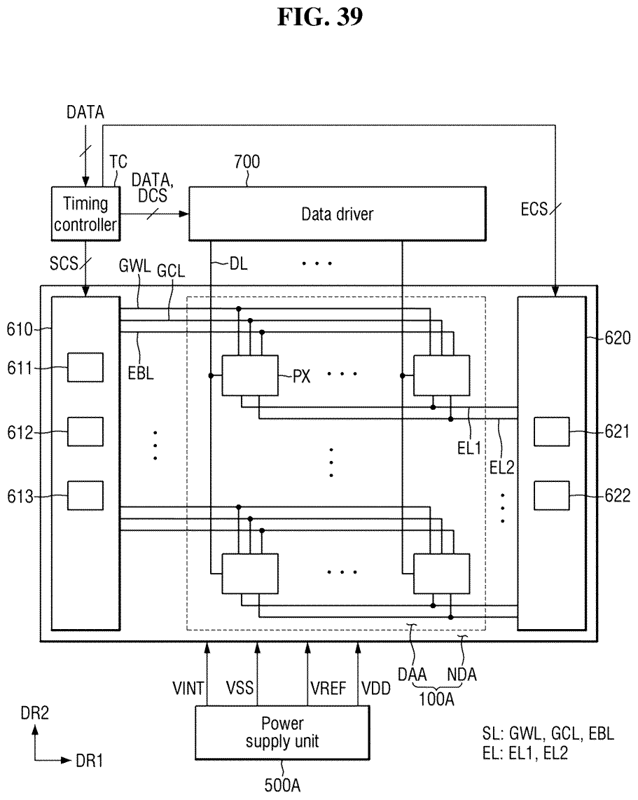

FIG. 37 is an exploded perspective view illustrating a display device according to an exemplary embodiment. FIG. 38 is a layout diagram illustrating an example of a display panel illustrated in FIG. 37. FIG. 39 is a block diagram illustrating the display device according to an exemplary embodiment.

Referring to FIGS. 37 and 38, a display device 10A according to an exemplary embodiment is a device that displays a moving image or a still image. The display device 10A according to an exemplary embodiment may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). As an example, the display device 10A may be applied as a display unit of televisions, laptop computers, monitors, billboards, or the Internet of Things (IOTs). Alternatively, the display device 10A may be applied to smart watches, watch phones, or head mounted displays (HMDs) for realizing virtual reality and augmented reality.

The display device 10A according to an exemplary embodiment includes a display panel 100A, a heat dissipation layer 200A, a circuit board 300A, and a driving circuit 400A.

The display panel 100A may have a shape similar to a quadrangular shape in plan view. For example, the display panel 100A may have a shape similar to a quadrangular shape, in plan view, having short sides in the first direction DR1 and long sides in the second direction DR2 crossing the first direction DR1. In the display panel 100A, a corner where the short side in the first direction DR1 and the long side in the second direction DR2 meet may be rounded with a predetermined curvature or right-angled. The shape of the display panel 100A in plan view is not limited to the quadrangular shape, and may be a shape similar to other polygonal shapes, a circular shape, or an elliptical shape. A shape of the display device 10A in plan view may follow the shape of the display panel 100A in plan view, but an exemplary embodiment of the present disclosure is not limited thereto.

The display panel 100A may include a display area DAA that displays an image and a non-display area NDA that does not display an image, as illustrated in FIG. 39.

The display area DAA includes a plurality of pixels PX, a plurality of scan lines SL, a plurality of emission control lines EL, and a plurality of data lines DL.

Each of the plurality of pixels PX includes a light emitting element emitting light. The plurality of pixels PX may be arranged in a matrix form in the first direction DR1 and the second direction DR2. The plurality of scan lines SL and the plurality of emission control lines EL may extend in the first direction DR1 and may be disposed in the second direction DR2. The plurality of data lines DL may extend in the second direction DR2 and may be disposed in the first direction DR1.

The plurality of scan lines SL includes a plurality of write scan lines GWL, a plurality of control scan lines GCL, and a plurality of bias scan lines EBL. The plurality of emission control lines EL include a plurality of first emission control lines EL1 and a plurality of second emission control lines EL2.

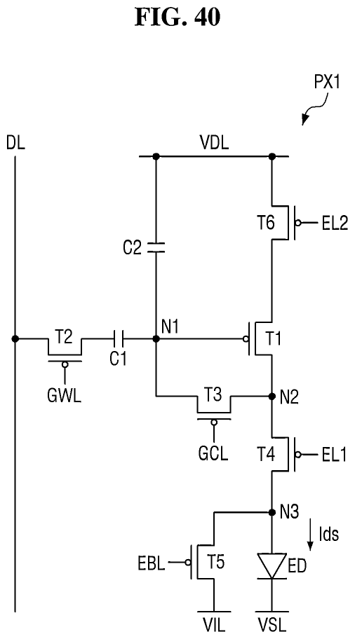

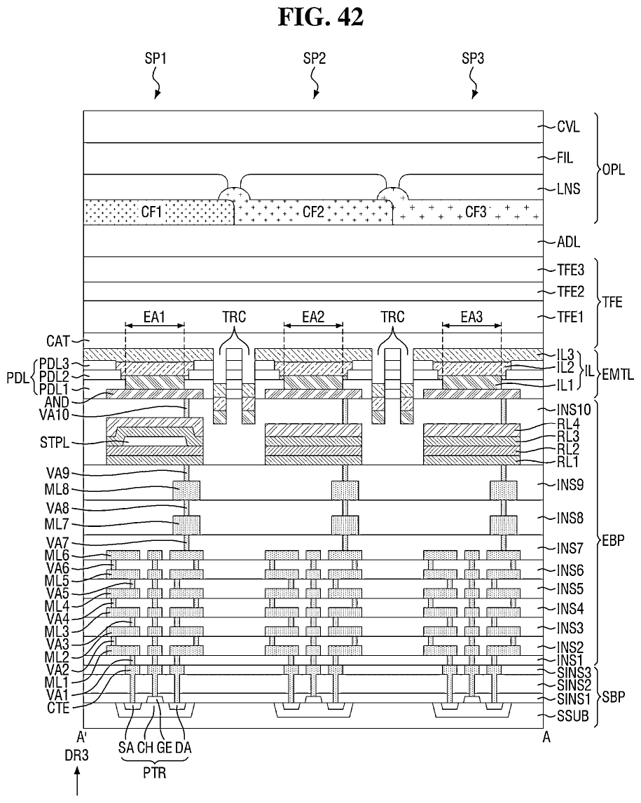

A plurality of unit pixels UPX include a plurality of pixels PX1, PX2, and PX3, see FIG. 6 for example. The plurality of pixels PX1, PX2, and PX3 may include a plurality of pixel transistors as illustrated in FIG. 40, and the plurality of pixel transistors may be formed by a semiconductor process and may be disposed on a semiconductor substrate SSUB (see FIG. 42). For example, the plurality of pixel transistors may be formed as complementary metal oxide semiconductors (CMOSs).

Each of the plurality of pixels PX1, PX2, and PX3 may be connected to any one of the plurality of write scan lines GWL, any one of the plurality of control scan lines GCL, any one of the plurality of bias scan lines EBL, any one of the plurality of first emission control lines EL1, any one of the plurality of second emission control lines EL2, and any one of the plurality of data lines DL. Each of the plurality of pixels PX1, PX2, and PX3 may receive a data voltage of the data line DL according to a write scan signal of the write scan line GWL, and allow the light emitting element to emit light according to the data voltage.

The non-display area NDA includes scan driving areas SDA, a data driving area DDA, and a pad area PDA, see FIG. 38 for example.

The scan driving areas SDA may be areas in which a scan driver 610 and an emission driver 620 are disposed. It has been illustrated in FIG. 38 that the scan driver 610 is disposed on the left side of the display area DAA and the emission driver 620 is disposed on the right side of the display area DAA, but an exemplary embodiment of the present disclosure is not limited thereto. For example, the scan drivers 610 and the emission drivers 620 may be disposed on both the left and right sides of the display area DAA.

The scan driver 610 includes a plurality of scan transistors, and the emission driver 620 includes a plurality of light emitting transistors. The plurality of scan transistors and the plurality of light emitting transistors may be formed by a semiconductor process and may be formed on the semiconductor substrate SSUB (see FIG. 42). For example, the plurality of scan transistors and the plurality of light emitting transistors may be formed as CMOSs.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from a timing controller TC. The write scan signal output unit 611 may generate write scan signals according to the scan timing control signal SCS of the timing controller TC and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines EBL.

The emission driver 620 includes a first emission control driver 621 and a second emission control driver 622. Each of the first emission control driver 621 and the second emission control driver 622 may receive an emission timing control signal ECS from the timing controller TC. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driving area DDA may be an area in which a data driver 700 is disposed. The data driver 700 may include a plurality of data transistors, and the plurality of data transistors may be formed by a semiconductor process and may be formed on the semiconductor substrate SSUB (see FIG. 42). For example, the plurality of data transistors may be formed as CMOSs.

The data driver 700 may receive digital video data DATA and a data timing control signal DCS from the timing controller TC. The data driver 700 converts the digital video data DATA into analog data voltages according to the data timing control signal DCS and outputs the converted analog data voltages to the data lines DL. In this case, the pixels PX1, PX2, and PX3 may be selected by the write scan signals of the scan driver 610, and the data voltages may be supplied to the selected pixels PX1, PX2, and PX3.

The pad area PDA includes a plurality of pads PD disposed in the first direction DR1. Each of the plurality of pads PD may be exposed without being covered by a cover layer CVL (see FIG. 42) and a polarizing plate (not illustrated).

The heat dissipation layer 200A may overlap the display panel 100A in the third direction DR3, which is a thickness direction of the display panel 100A. The heat dissipation layer 200A may be disposed on one surface, for example, a rear surface, of the display panel 100A. The heat dissipation layer 200A serves to dissipate heat generated from the display panel 100A. The heat dissipation layer 130 may include a metal layer such as graphite, silver (Ag), copper (Cu), or aluminum (Al) having high thermal conductivity.

The circuit board 300A may be electrically connected to the plurality of pads PD of the pad area PDA of the display panel 100A using a conductive adhesive member such as an anisotropic conductive film. The circuit board 300A may be a flexible printed circuit board or a flexible film having a flexible material. It has been illustrated in FIG. 37 that the circuit board 300A is unbent, but the circuit board 300A may be bent. In this case, one end of the circuit board 300A may be disposed on the rear surface of the display panel 100A. One end of the circuit board 300A may be an end opposite to the other end of the circuit board 300A connected to the plurality of pads PD of the pad area PDA of the display panel 100A using the conductive adhesive member.

The timing controller TC may receive digital video data and timing signals from the outside. The timing controller TC may generate the scan timing control signal SCS, the emission timing control signal ECS, and the data timing control signal DCS for controlling the display panel 100A according to the timing signals. The timing controller TC may output the scan timing control signal SCS to the scan driver 610 and output the emission timing control signal ECS to the emission driver 620. The timing controller TC may output the digital video data and the data timing control signal DCS to the data driver 700.

A power supply unit 500A may generate a plurality of panel driving voltages according to an external source voltage. For example, the power supply unit 500A may generate a first driving voltage VSS, a second driving voltage VDD, a third driving voltage VINT, and a reference voltage VREF and supply the first driving voltage VSS, the second driving voltage VDD, the third driving voltage VINT, and the reference voltage VREF to the display panel 100. The first driving voltage VSS, the second driving voltage VDD, and the third driving voltage VINT will be described later with reference to FIG. 39.

Each of the timing controller TC and the power supply unit 500A may be formed as an integrated circuit (IC) and attached to one surface of the circuit board 300A. The scan timing control signal SCS, the emission timing control signal ECS, the digital video data DATA, and the data timing control signal DCS of the timing controller TC may be supplied to the display panel 100A through the circuit board 300A. The first driving voltage VSS, the second driving voltage VDD, and the third driving voltage VINT of the power supply unit 500A may be supplied to the display panel 100A through the circuit board 300A.

FIG. 40 is an equivalent circuit diagram of a first pixel PX1 according to an exemplary embodiment.

Referring to FIG. 40, the first pixel PX1 may be connected to a write scan line GWL, a control scan line GCL, a bias scan line EBL, a first emission control line EL1, a second emission control line EL2, and a data line DL. In addition, the first pixel PX1 may be connected to a first driving voltage line VSL to which a first driving voltage VSS corresponding to a low potential voltage is applied, a second driving voltage line VDL to which a second driving voltage VDD corresponding to a high potential voltage is applied, and a third driving voltage line VIL to which a third driving voltage VINT corresponding to an initialization voltage is applied That is, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be a voltage higher than the third driving voltage VINT.

The first pixel PX1 includes a plurality of transistors T1 to T6, a light emitting element ED, a first capacitor C1, and a second capacitor C2.

The light emitting element ED emits light according to a driving current Ids flowing through a channel of the first transistor T1. An amount of light emitted from the light emitting element ED may be proportional to the driving current Ids. The light emitting element ED may be disposed between the fourth transistor T4 and the first driving voltage line VSL. A first electrode of the light emitting element ED may be connected to a drain electrode of the fourth transistor T4, and a second electrode of the light emitting element ED may be connected to the first driving voltage line VSL. The first electrode of the light emitting element ED may be an anode electrode, and the second electrode of the light emitting element ED may be a cathode electrode. The light emitting element ED may be an organic light emitting diode including a first electrode, a second electrode, and an organic light emitting layer disposed between the first electrode and the second electrode, but an exemplary embodiment of the present disclosure is not limited thereto. For example, the light emitting element ED may be an inorganic light emitting element including a first electrode, a second electrode, and an inorganic semiconductor disposed between the first electrode and the second electrode, and in this case, the light emitting element ED may be a micro light emitting diode.

The first transistor T1 may be a driving transistor controlling a source-drain current Ids (hereinafter referred to as a “driving current”) flowing between a source electrode and a drain electrode according to a voltage applied to a gate electrode thereof. The first transistor T1 includes the gate electrode connected to a first node N1, the source electrode connected to a drain electrode of the sixth transistor T6, and the drain electrode connected to a second node N2.

The second transistor T2 may be disposed between one electrode of the first capacitor C1 and the data line DL. The second transistor T2 is turned on by a write scan signal of the write scan line GWL to connect one electrode of the first capacitor C1 to the data line DL. Accordingly, a data voltage of the data line DL may be applied to one electrode of the first capacitor C1. The second transistor T2 includes a gate electrode connected to the write scan line GWL, a source electrode connected to the data line DL, and a drain electrode connected to one electrode of the first capacitor C1.

The third transistor T3 may be disposed between the first node N1 and the second node N2. The third transistor T3 is turned on by a control scan signal of the control scan line GCL to connect the first node N1 to the second node N2. For this reason, the gate electrode and the drain electrode of the first transistor T1 are connected to each other, and thus, the first transistor T1 may operate like a diode. The third transistor T3 includes a gate electrode connected to the control scan line GCL, a source electrode connected to the second node N2, and a drain electrode connected to the first node N1.

The fourth transistor T4 may be connected between the second node N2 and a third node N3. The fourth transistor ST4 is turned on by a first emission control signal of the first emission control line EL1 to connect the second node N2 to the third node N3. For this reason, the driving current of the first transistor T1 may be supplied to the light emitting element ED. The fourth transistor T4 includes a gate electrode connected to the first emission control line EL1, a source electrode connected to the second node N2, and the drain electrode connected to the third node N3.

The fifth transistor T5 may be disposed between the third node N3 and the third driving voltage line VIL. The fifth transistor T5 is turned on by a bias scan signal of the bias scan line EBL to connect the third node N3 to the third driving voltage line VIL. For this reason, the third driving voltage VINT of the third driving voltage line VIL may be applied to the first electrode of the light emitting element ED. The fifth transistor T5 includes a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by a second emission control signal of the second emission control line EL2 to connect the source electrode of the first transistor T1 to the second driving voltage line VDL. For this reason, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and the drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2 and the other electrode connected to the first node N1.

The second capacitor C2 is formed between the gate electrode of the first transistor T1 and the second driving voltage line VDL. The second capacitor C2 includes one electrode connected to the gate electrode of the first transistor T1 and the other electrode connected to the second driving voltage line VDL.

The first node N1 is a contact point between the gate electrode of the first transistor T1, the drain electrode of the third transistor T3, the other electrode of the first capacitor C1, and one electrode of the second capacitor C2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element ED.

Each of the first to sixth transistors T1 to T6 may be a metal oxide semiconductor field effect transistor (MOSFET). For example, each of the first to sixth transistors T1 to T6 may be a P-type MOSFET, but an exemplary embodiment of the present disclosure is not limited thereto. Each of the first to sixth transistors T1 to T6 may be an N-type MOSFET. Alternatively, some of the first to sixth transistors T1 to T6 may be P-type MOSFETs, and the others of the first to sixth transistors T1 to T6 may be N-type MOSFETs.

It has been illustrated in FIG. 40 that the first pixel PX1 includes six transistors T1 to T6 and two capacitors C1 and C2, but it is to be noted that an equivalent circuit diagram of the first pixel PX1 is not limited to that illustrated in FIG. 40. For example, the numbers of transistors and capacitors of the first pixel PX1 are not limited to those illustrated in FIG. 40.

In addition, an equivalent circuit diagram of the second pixel PX2 and an equivalent circuit diagram of the third pixel PX3 may be substantially the same as the equivalent circuit diagram of the first pixel PX1 described with reference to FIG. 40. Therefore, descriptions of the equivalent circuit diagram of the second pixel PX2 and the equivalent circuit diagram of the third pixel PX3 are omitted in the present disclosure.

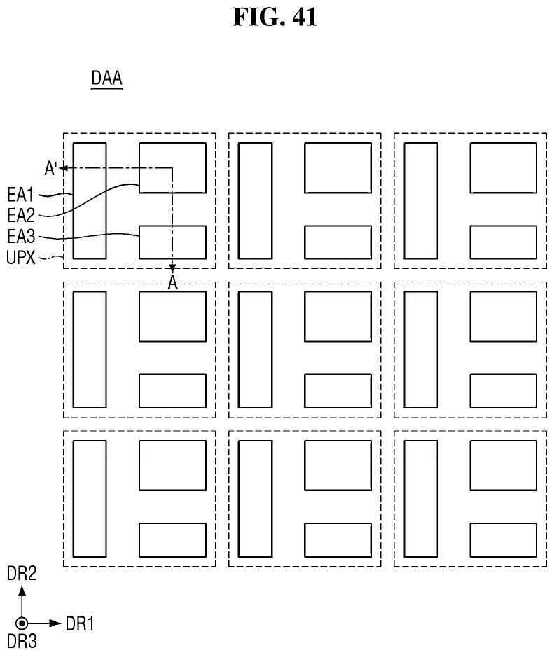

FIG. 41 is a layout diagram illustrating pixels of a display area according to an exemplary embodiment.

Referring to FIG. 41, each of the plurality of unit pixels UPX may include a first emission area EA1 that is an emission area of the first pixel PX1, a second emission area EA2 that is an emission area of the second pixel PX2, and a third emission area EA3 that is an emission area of the third pixel PX3.

Each of the first emission area EA1, the second emission area EA2, and the third emission area EA3 may have a quadrangular shape such as a rectangular shape, a square shape, or a rhombic shape in plan view. For example, the first emission area EA1 may have a rectangular shape, in plan view, having short sides in the first direction DR1 and long sides in the second direction DR2. In addition, each of the second emission area EA2 and the third emission area EA3 may have a rectangular shape, in plan view, having long sides in the first direction DR1 and short sides in the second direction DR2.

A length of the first emission area EA1 in the first direction DR1 may be smaller than a length of the second emission area EA2 in the first direction DR1 and smaller than a length of the third emission area EA3 in the first direction DR1. The length of the second emission area EA2 in the first direction DR1 and the length of the third emission area EA3 in the first direction DR1 may be substantially the same as each other.

A length of the first emission area EA1 in the second direction DR2 may be greater than the sum of a length of the second emission area EA2 in the second direction DR2 and a length of the third emission area EA3 in the second direction DR2. The length of the second emission area EA2 in the second direction DR2 may be smaller than the length of the third emission area EA3 in the second direction DR2.

It has been illustrated in FIG. 41 that each of the first emission area EA1, the second emission area EA2, and the third emission area EA3 has the quadrangular shape in plan view, but an exemplary embodiment of the present disclosure is not limited thereto. For example, each of the first emission area EA1, the second emission area EA2, and the third emission area EA3 may have other polygonal shapes other than the quadrangular shape, a circular shape, or an elliptical shape in plan view.

In each of the plurality of unit pixels UPX, the first emission area EA1 and the second emission area EA2 may neighbor to each other in the first direction DR1. In addition, the first emission area EA1 and the third emission area EA3 may neighbor to each other in the first direction DR1. In addition, the second emission area EA2 and the third emission area EA3 may neighbor to each other in the second direction DR2. An area of the first emission area EA1, an area of the second emission area EA2, and an area of the third emission area EA3 may be different from each other.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may indicate that a main peak wavelength of the light is included in a wavelength range of approximately 370 nm to 460 nm, the green wavelength band may indicate that a main peak wavelength of the light is included in a wavelength range of approximately 480 nm to 560 nm, and the red wavelength band may indicate that a main peak wavelength of the light is included in a wavelength band between approximately 600 nm and 750 nm.

It has been illustrated in FIG. 41 that each of the plurality of unit pixels UPX includes three emission areas EA1, EA2, and EA3, but an exemplary embodiment of the present disclosure is not limited thereto. That is, each of the plurality of unit pixels UPX may also include four emission areas.

In addition, an arrangement of the emission areas of the plurality of unit pixels UPX is not limited to that illustrated in FIG. 41. For example, the emission areas of the plurality of unit pixels UPX may be disposed in a stripe structure in which the emission areas are arranged in the first direction DR1, a PenTile® structure in which the emission areas have a diamond arrangement, or a hexagonal structure in which emission areas having a hexagonal shape in plan view are arranged.

FIG. 42 is a cross-sectional view illustrating an example of a display device taken along line A-A′ of FIG. 41.

Referring to FIG. 42, the display panel 100 includes a semiconductor backplane SBP, a light emitting element backplane EBP, a light emitting element layer EMTL, an encapsulation layer TFE, an optical layer OPL, the cover layer CVL, and a polarizing plate.

The semiconductor backplane SBP may include the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 40.

The semiconductor substrate SSUB may be a silicon substrate, a germanium substrate, or a silicon-germanium substrate. The semiconductor substrate SSUB may be a substrate doped with first-type impurities. A plurality of well regions may be disposed in an upper surface of the semiconductor substrate SSUB. The plurality of well regions may be regions doped with second-type impurities. The second-type impurities may be different from the first-type impurities described above. For example, when the first-type impurities are p-type impurities, the second-type impurities may be n-type impurities. Alternatively, when the first-type impurities are n-type impurities, the second-type impurities may be p-type impurities.

Each of the plurality of well regions includes a source region SA corresponding to a source electrode of the pixel transistor PTR, a drain region DA corresponding to a drain electrode of the pixel transistor PTR, and a channel region CH disposed between the source region SA and the drain region DA.

Each of the source region SA and the drain region DA may be a region doped with the first-type impurities. A gate electrode GE of the pixel transistor PTR may overlap the well region in the third direction DR3. The channel region CH may overlap the gate electrode GE in the third direction DR3. The source area SA may be disposed on one side of the gate electrode GE, and the drain area SA may be disposed on the other side of the gate electrode GE.

Each of the plurality of well regions further includes a first low-concentration impurity region disposed between the channel region CH and the source region SA and a second low-concentration impurity region disposed between the channel region CH and the drain region DA. The first low-concentration impurity region may have an impurity concentration lower than that of the source region SA. The second low-concentration impurity region may have an impurity concentration lower than that of the drain region DA. A distance between the source region SA and the drain region DA may increase by the first low-concentration impurity region and the second low-concentration impurity region. Therefore, a length of the channel region CH of each of the pixel transistors PTR may increase, and thus, punch-through and hot carrier phenomena caused by a short channel may be prevented.

A first semiconductor insulating film SINS1 may be disposed on the semiconductor substrate SSUB. The first semiconductor insulating film SINS1 may be formed as a silicon nitride (SiCN) or silicon oxide (SiOₓ)-based inorganic film, but an exemplary embodiment of the present disclosure is not limited thereto.

A second semiconductor insulating film SINS2 may be disposed on the first semiconductor insulating film SINS1. The second semiconductor insulating film SINS2 may be formed as a silicon oxide (SiOₓ)-based inorganic film, but an exemplary embodiment of the present disclosure is not limited thereto.

The plurality of contact terminals CTE may be disposed on the second semiconductor insulating film SINS2. Each of the plurality of contact terminals CTE may be connected to any one of the gate electrode GE, the source region SA, and the drain area DA of each of the pixel transistors PTR through a hole penetrating through the first semiconductor insulating film SINS1 and the second semiconductor insulating film SINS2. Each of the plurality of contact terminals CTE may be made of any one of copper (Cu), aluminum (Al), tungsten (W), molybdenum (Mo), chromium (Cr), gold (Au), titanium (Ti), nickel (Ni), and neodymium (Nd), or alloys thereof.

A third semiconductor insulating film SINS3 may be disposed on side surfaces of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but an exemplary embodiment of the present disclosure is not limited thereto.

The semiconductor substrate SSUB may be replaced with a glass substrate or a polymer resin substrate such as a polyimide substrate. In this case, thin film transistors may be disposed on the glass substrate or the polymer resin substrate. The glass substrate may be a rigid substrate that is not bent, and the polymer resin substrate may be a flexible substrate that may be bent.

The light emitting element backplane EBP includes first to eighth metal layers ML1 to ML8, reflective electrodes RL1 to RL4, a plurality of vias VA1 to VA10, and a stepped layer STPL. In addition, the light emitting element backplane EBP includes a plurality of interlayer insulating films INS1 to INS10 disposed between the first to eighth metal layers ML1 to ML8.

The first to eighth metal layers ML1 to ML8 serve to implement a circuit of the first pixel PX1 illustrated in FIG. 40 by connecting the plurality of contact terminals CTE exposed from the semiconductor backplane SBP to each other. That is, only the first to sixth transistors T1 to T6 are formed in the semiconductor backplane SBP, and the connection between the first to sixth transistors T1 to T6 and the formation of the first capacitor C1 and the second capacitor C2 are performed through the first to eighth metal layers ML1 to ML8. In addition, the connection between the drain region corresponding to the drain electrode of the fourth transistor T4, the source region corresponding to the source electrode of the fifth transistor T5, and the first electrode of the light emitting element ED is also performed through the first to eighth metal layers ML1 to ML8.

The first interlayer insulating film INS1 may be disposed on the semiconductor backplane SBP. Each of first vias VA1 may penetrate through the first interlayer insulating film INS1 to be connected to the contact terminal CTE exposed from the semiconductor backplane SBP. Each of the first metal layers ML1 may be disposed on the first interlayer insulating film INS1 and be connected to the first via VA1.

The second interlayer insulating film INS2 may be disposed on the first interlayer insulating film INS1 and the first metal layers ML1. Each of second vias VA2 may penetrate through the second interlayer insulating film INS2 to be connected to the exposed first metal layer ML1. Each of the second metal layers ML2 may be disposed on the second interlayer insulating film INS2 and be connected to the second via VA2.

The third interlayer insulating film INS3 may be disposed on the second interlayer insulating film INS2 and the second metal layers ML2. Each of third vias VA3 may penetrate through the third interlayer insulating film INS3 to be connected to the exposed second metal layer ML2. Each of the third metal layers ML3 may be disposed on the third interlayer insulating film INS3 and be connected to the third via VA3.

The fourth interlayer insulating film INS4 may be disposed on the third interlayer insulating film INS3 and the third metal layers ML3. Each of fourth vias VA4 may penetrate through the fourth interlayer insulating film INS4 to be connected to the exposed third metal layer ML3. Each of the fourth metal layers ML4 may be disposed on the fourth interlayer insulating film INS4 and be connected to the fourth via VA4.

The fifth interlayer insulating film INS5 may be disposed on the fourth interlayer insulating film INS4 and the fourth metal layers ML4. Each of fifth vias VA5 may penetrate through the fifth interlayer insulating film INS5 to be connected to the exposed fourth metal layer ML4. Each of the fifth metal layers ML5 may be disposed on the fifth interlayer insulating film INS5 and be connected to the fifth via VA5.

The sixth interlayer insulating film INS6 may be disposed on the fifth interlayer insulating film INS5 and the fifth metal layers ML5. Each of sixth vias VA6 may penetrate through the sixth interlayer insulating film INS6 to be connected to the exposed fifth metal layer ML5. Each of the sixth metal layers ML6 may be disposed on the sixth interlayer insulating film INS6 and be connected to the sixth via VA6.

The seventh interlayer insulating film INS7 may be disposed on the sixth interlayer insulating film INS6 and the sixth metal layers ML6. Each of seventh vias VA7 may penetrate through the seventh interlayer insulating film INS7 to be connected to the exposed sixth metal layer ML6. Each of the seventh metal layers ML7 may be disposed on the seventh interlayer insulating film INS7 and be connected to the seventh via VA7.

The eighth interlayer insulating film INS8 may be disposed on the seventh interlayer insulating film INS7 and the seventh metal layers ML7. Each of eighth vias VA8 may penetrate through the eighth interlayer insulating film INS8 to be connected to the exposed seventh metal layer ML7. Each of the eighth metal layers ML8 may be disposed on the eighth interlayer insulating film INS8 and be connected to the eighth via VA8.

The first to eighth metal layers ML1 to ML8 and the first to eighth vias VA1 to VA8 may be made of substantially the same material. Each of the first to eighth metal layers ML1 to ML8 and the first to eighth vias VA1 to VA8 may be made of any one of copper (Cu), aluminum (Al), tungsten (W), molybdenum (Mo), chromium (Cr), gold (Au), titanium (Ti), nickel (Ni), and neodymium (Nd), or alloys thereof. The first to eighth vias VA1 to VA8 may be made of substantially the same material. The first to eighth interlayer insulating films INS1 to INS8 may be formed as silicon oxide (SiOₓ)-based inorganic films, but an exemplary embodiment of the present disclosure is not limited thereto.

Each of a thickness of the first metal layer ML1, a thickness of the second metal layer ML2, a thickness of the third metal layer ML3, a thickness of the fourth metal layer ML4, a thickness of the fifth metal layer ML5, and a thickness of the sixth metal layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same as each other. For example, the thickness of the first metal layer ML1 may be approximately 1360 Å, each of the thickness of the second metal layer ML2, the thickness of the third metal layer ML3, the thickness of the fourth metal layer ML4, the thickness of the fifth metal layer ML5, and the thickness of the sixth metal layer ML6 may be approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 may be approximately 1150 Å.

Each of a thickness of the seventh metal layer ML7 and a thickness of the eighth metal layer ML8 may be greater than each of the thickness of the first metal layer ML1, the thickness of the second metal layer ML2, the thickness of the third metal layer ML3, the thickness of the fourth metal layer ML4, the thickness of the fifth metal layer ML5, and the thickness of the sixth metal layer ML6. Each of the thickness of the seventh metal layer ML7 and the eighth metal layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be substantially the same as each other. For example, each of the thickness of the seventh metal layer ML7 and the thickness of the eighth metal layer ML8 may be approximately 9000 Å. Each of the thickness of the seventh via VA7 and the thickness of the eighth via VA8 may be approximately 6000 Å.

The ninth interlayer insulating film INS9 may be disposed on the eighth interlayer insulating film INS8 and the eighth metal layers ML8. The ninth interlayer insulating film INS9 may be formed as a silicon oxide (SiOₓ)-based inorganic film, but an exemplary embodiment of the present disclosure is not limited thereto.

Each of ninth vias VA9 may penetrate through the ninth interlayer insulating film INS9 to be connected to the exposed eighth metal layer ML8. Each of the ninth vias VA9 may be made of any one of copper (Cu), aluminum (Al), tungsten (W), molybdenum (Mo), chromium (Cr), gold (Au), titanium (Ti), nickel (Ni), and neodymium (Nd), or alloys thereof. A thickness of the ninth via VA9 may be approximately 16500 Å.

Each of the first reflective electrodes RL1 may be disposed on the ninth interlayer insulating film INS9 and be connected to the ninth via VA9. Each of the first reflective electrodes RL1 may be made of any one of copper (Cu), aluminum (Al), tungsten (W), molybdenum (Mo), chromium (Cr), gold (Au), titanium (Ti), nickel (Ni), and neodymium (Nd), or alloys thereof.

Each of the second reflective electrodes RL2 may be disposed on the first reflective electrode RL1. Each of the second reflective electrodes RL2 may be made of any one of copper (Cu), aluminum (Al), tungsten (W), molybdenum (Mo), chromium (Cr), gold (Au), titanium (Ti), nickel (Ni), and neodymium (Nd), or alloys thereof. For example, each of the second reflective electrodes RL2 may be made of titanium nitride (TiN).

In the first pixel PX1, the stepped layer STPL may be disposed on the second reflective electrode RL2. The stepped layer STPL may not be disposed in each of the second pixel PX2 and the third pixel PX3. A thickness of the stepped layer STPL may be set in consideration of a wavelength of light of a first color and a distance from a first light emitting layer of the first pixel PX1 to a fourth reflective electrode RL4 so as to be advantageous in reflecting the light of the first color emitted from the first light emitting layer of the first pixel PX1. The stepped layer STPL may be formed as a silicon nitride (SiCN) or silicon oxide (SiOₓ)-based inorganic film, but an exemplary embodiment of the present disclosure is not limited thereto. A thickness of the stepped layer STPL may be approximately 400 Å.

In the first pixel PX1, a third reflective electrode RL3 may be disposed on the second reflective electrode RL2 and the stepped layer STPL. In the second pixel PX2 and the third pixel PX3, third reflective electrodes RL3 may be disposed on the second reflective electrodes RL2. Each of the third reflective electrodes RL3 may be made of any one of copper (Cu), aluminum (Al), tungsten (W), molybdenum (Mo), chromium (Cr), gold (Au), titanium (Ti), nickel (Ni), and neodymium (Nd), or alloys thereof.

At least one of the first reflective electrodes RL1, the second reflective electrodes RL2, and the third reflective electrodes RL3 may be omitted.

Each of fourth reflective electrodes RL4 may be disposed on the third reflective electrode RL3. The fourth reflective electrodes RL4 may be layers reflecting light from first to third intermediate layers IL1, IL2, and IL3. The fourth reflective electrodes RL4 may include a metal having high reflectivity so as to be advantageous in reflecting the light. Each of the fourth reflective electrodes RL4 may be made of aluminum (Al), a stacked structure (Ti/Al/Ti) of aluminum and titanium, a stacked structure (ITO/Al/ITO) of aluminum and ITO, silver (Ag), palladium (Pd), an APC alloy, which is an alloy of copper (Cu), and a stacked structure (ITO/APC/ITO) of an APC alloy and ITO, but an exemplary embodiment of the present disclosure is not limited thereto. A thickness of each of the fourth reflective electrodes RL4 may be approximately 850 Å.

A tenth interlayer insulating film INS10 may be disposed on the ninth interlayer insulating film INS9 and the fourth reflective electrodes RL4. The tenth interlayer insulating film INS10 may be formed as a silicon oxide (SiOₓ)-based inorganic film, but an exemplary embodiment of the present disclosure is not limited thereto.

Each of tenth vias VA10 may penetrate through the tenth interlayer insulating film VA10 to be connected to the exposed fourth reflective electrode RL4. Each of the tenth vias VA10 may be made of any one of copper (Cu), aluminum (Al), tungsten (W), molybdenum (Mo), chromium (Cr), gold (Au), titanium (Ti), nickel (Ni), and neodymium (Nd), or alloys thereof. Due to the stepped layer STPL, a thickness of the tenth via VA10 in the first pixel PX1 may be smaller than a thickness of the tenth via VA10 in each of the second pixel PX2 and the third pixel PX3. For example, the thickness of the tenth via VA10 in the first pixel PX1 may be approximately 800 Å, and the thickness of the tenth via VA10 in each of the second pixel PX2 and the third pixel PX3 may be approximately 1200 Å.

The light emitting element layer EMTL may be disposed on the light emitting element backplane EBP. The light emitting element layer EMTL may include light emitting elements each including a first electrode AND, an intermediate layer IL, and a second electrode CAT, a pixel defining film PDL, and a plurality of trenches TRC.

The first electrode AND of each of the light emitting elements may be disposed on the tenth interlayer insulating film INS10 and be connected to the tenth via VA10. The first electrode AND of each of the light emitting elements may be connected to the drain region DA or the source region SA of the pixel transistor PTR through the tenth via VA10, the first to fourth reflective electrodes RL1 to RL4, the first to ninth vias VA1 to VA9, the first to eighth metal layers ML1 to ML8, and the contact terminal CTE. The first electrode AND of each of the light emitting elements ED may be made of any one of copper (Cu), aluminum (Al), tungsten (W), molybdenum (Mo), chromium (Cr), gold (Au), titanium (Ti), nickel (Ni), and neodymium (Nd), or alloys thereof. For example, the first electrode AND of each of the light emitting elements ED may be made of titanium nitride (TiN).

The pixel defining film PDL may be disposed on a partial area of the first electrode AND of each of the light emitting elements. The pixel defining film PDL may cover an edge of the first electrode AND of each of the light emitting elements. The pixel defining film PDL serves to partition first emission areas EA1, second emission areas EA2, and third emission areas EA3.

The first emission area EA1 may be defined as an area in which the first electrode AND, the intermediate layer IL, and the second electrode CAT are sequentially stacked in the first pixel PX1 to emit light. The second emission area EA2 may be defined as an area in which the first electrode AND, the intermediate layer IL, and the second electrode CAT are sequentially stacked in the second pixel PX2 to emit light. The third emission area EA3 may be defined as an area in which the first electrode AND, the intermediate layer IL, and the second electrode CAT are sequentially stacked in the third pixel PX3 to emit light.

The pixel defining film PDL may include first to third pixel defining films PDL1, PDL2, and PDL3. The first pixel defining film PDL1 may be disposed on the edge of the first electrode AND of each of the light emitting elements ED, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as silicon oxide (SiOₓ)-based inorganic films, but an exemplary embodiment of the present disclosure is not limited thereto. Each of a thickness of the first pixel defining film PDL1, a thickness of the second pixel defining film PDL2, and a thickness of the third pixel defining film PDL3 may be approximately 500 Å.

Each of the plurality of trenches TRC may penetrate through the first pixel defining film PDL1, the second pixel defining film PDL2, and the third pixel defining film PDL3. In each of the plurality of trenches TRC, the tenth interlayer insulating film INS10 may have a shape in which a portion thereof trenches.

At least one trench TRC may be disposed between the pixels PX1, PX2, and PX3 neighboring to each other. It has been illustrated in FIG. 42 that two trenches TRC are disposed between the pixels PX1, PX2, and PX3 neighboring to each other, but an exemplary embodiment of the present disclosure is not limited thereto.

The intermediate layer IL may include the first intermediate layer IL1, the second intermediate layer IL2, and the third intermediate layer IL3.

The intermediate layer IL may have a tandem structure including a plurality of intermediate layers IL1, IL2, and IL3 emitting different light. For example, the intermediate layer IL may include a first intermediate layer IL1 emitting light of a first color, a second intermediate layer IL2 emitting light of a third color, and a third intermediate layer IL3 emitting light of a second color. The first intermediate layer IL1, the second intermediate layer IL2, and the third intermediate layer IL3 may be sequentially stacked.

The first intermediate layer IL1 may have a structure in which a first hole transport layer, a first organic light emitting layer emitting the light of the first color, and a first electron transport layer are sequentially stacked. The second intermediate layer IL2 may have a structure in which a second hole transport layer, a second organic light emitting layer emitting the light of the third color, and a second electron transport layer are sequentially stacked. The third intermediate layer IL3 may have a structure in which a third hole transport layer, a third organic light emitting layer emitting the light of the second color, and a third electron transport layer are sequentially stacked.

A first charge generation layer for supplying charges to the second intermediate layer IL2 and supplying electrons to the first intermediate layer IL1 may be disposed between the first intermediate layer IL1 and the second intermediate layer IL2. A second charge generation layer for supplying charges to the third intermediate layer IL3 and supplying electrons to the second intermediate layer IL2 may be disposed between the second intermediate layer IL2 and the third intermediate layer IL3.

The first intermediate layer IL1 may be disposed on the first electrodes AND and the pixel defining film PDL, and may be disposed on a bottom surface of each of the trenches TRC. Due to the trenches TRC, the first intermediate layer IL1 may be disconnected between the pixels PX1, PX2, and PX3 neighboring to each other. The second intermediate layer IL2 may be disposed on the first intermediate layer IL1. Due to the trenches TRC, the second intermediate layer IL2 may be disconnected between the pixels PX1, PX2, and PX3 neighboring to each other. The third intermediate layer IL3 may be disposed on the second intermediate layer IL2. Due to the trenches TRC, the third intermediate layer IL3 may be disconnected between the pixels PX1, PX2, and PX3 neighboring to each other. That is, each of the plurality of trenches TRC may be a structure for disconnecting the first to third intermediate layers IL1, IL2, and IL3 of the light emitting element layer EMTL between the pixels PX1, PX2, and PX3 neighboring to each other.

In order to stably disconnect the first to third intermediate layers IL1, IL2, and IL3 of the light emitting element layer EMTL between the pixels PX1, PX2, and PX3 neighboring to each other, a height of each of the plurality of trenches TRC may be greater than a height of the pixel defining film PDL. The height of each of the plurality of trenches TRC refers to a length of each of the plurality of trenches TRC in the third direction DR3. The height of the pixel defining film PDL refers to a length of the pixel defining film PDL in the third direction DR3.

In order to disconnect the first to third intermediate layers IL1, IL2, and IL3 of the light emitting element layer EMTL between the pixels PX1, PX2, and PX3 neighboring to each other, other structures may exist instead of the trenches TRC. For example, instead of the trenches TRC, partition walls having a reverse tapered shape may be disposed on the pixel defining film PDL.

The number of intermediate layers IL1, IL2, and IL3 emitting the different light is not limited to that illustrated in FIG. 42. For example, the intermediate layer IL may include two intermediate layers. In this case, any one of the two intermediate layers may be substantially the same as the first intermediate layer IL1, and the other of the two intermediate layers may include a second hole transport layer, a second organic light emitting layer, a third organic light emitting layer, and a second electron transport layer. In this case, a charge generation layer for supplying electrons to any one intermediate layer and supplying charges to the other intermediate layer may be disposed between the two intermediate layers.

It has been illustrated in FIG. 42 that the first to third intermediate layers IL1, IL2, and IL3 are all disposed in the first emission area EA1, the second emission area EA2, and the third emission area EA3, but an exemplary embodiment of the present disclosure is not limited thereto. For example, the first intermediate layer IL1 may be disposed in the first emission area EA1, and may not be disposed in the second emission area EA2 and the third emission area EA3. In addition, the second intermediate layer IL2 may be disposed in the second emission area EA2, and may not be disposed in the first emission area EA1 and the third emission area EA3. In addition, the third intermediate layer IL3 may be disposed in the third emission area EA3, and may not be disposed on the first emission area EA1 and the second emission area EA2. In this case, first to third color filters CF1, CF2, and CF3 of the optical layer OPL may be omitted.

The second electrode CAT may be disposed on the third intermediate layer IL3. The second electrode CAT may be disposed on the third intermediate layer IL3 in each of the plurality of trenches TRC. The second electrode CAT may be made of a transparent conductive material (TCO) such as ITO or IZO capable of transmitting light therethrough or a semi-transmissive conductive material such as magnesium (Mg), silver (Ag), or an alloy of magnesium (Mg) and silver (Ag). When the second electrode CAT is made of the semi-transmissive conductive material, emission efficiency of each of the first to third pixels PX1, PX2, and PX3 may be increased by a micro cavity.

The encapsulation layer TFE may be disposed on the light emitting element layer EMTL. The encapsulation layer TFE may include at least one inorganic film TFE1 or TFE3 in order to prevent oxygen or moisture from permeating into the light emitting element layer EMTL. In addition, the encapsulation layer TFE may include at least one organic film in order to protect the light emitting element layer EMTL from foreign substances such as dust. For example, the encapsulation layer TFE may include a first encapsulation inorganic film TFE1, an encapsulation organic film TFE2, and a second encapsulation inorganic film TFE3.

The first encapsulation inorganic film TFE1 may be disposed on the second electrode CAT, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the third encapsulation inorganic film TFE3 may be formed as multiple films in which one or more inorganic films of a silicon nitride (SiNₓ) layer, a silicon oxynitride (SiON) layer, a silicon oxide (SiOₓ) layer, a titanium oxide (TiOₓ) layer, and an aluminum oxide (AlOₓ) layer are alternately stacked. The encapsulation organic film TFE2 may be made of a monomer. Alternatively, the encapsulation organic film TFE2 may be an organic film made of an acrylic resin, an epoxy resin, a phenolic resin, a polyamide resin, a polyimide resin, or the like.

An adhesive layer ADL may be a layer for adhering the encapsulation layer TFE and the optical layer OPL to each other. The adhesive layer ADL may be a double-sided adhesive member. In addition, the adhesive layer ADL may be a transparent adhesive member such as a transparent adhesive or a transparent adhesive resin.

The optical layer OPL includes the plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be disposed on the adhesive layer ADL.

The first color filter CF1 may overlap the first emission area EA1 of the first pixel PX1. The first color filter CF1 may transmit the light of the first color, that is, light of a blue wavelength band, therethrough. The blue wavelength band may be approximately 370 nm to 460 nm. Therefore, the first color filter CF1 may transmit the light of the first color among light emitted from the first emission area EA1 therethrough.

The second color filter CF2 may overlap the second emission area EA2 of the second pixel PX2. The second color filter CF2 may transmit the light of the second color, that is, light of a green wavelength band, therethrough. The green wavelength band may be approximately 480 nm to 560 nm. Therefore, the second color filter CF2 may transmit the light of the second color among light emitted from the second emission area EA2 therethrough.

The third color filter CF3 may overlap the third emission area EA3 of the third pixel PX3. The third color filter CF3 may transmit the light of the third color, that is, light of a red wavelength band, therethrough. The blue wavelength band may be approximately 600 nm to 750 nm. Therefore, the third color filter CF3 may transmit the light of the third color among light emitted from the third emission area EA3 therethrough.

Each of the plurality of lenses LNS may be disposed on each of the first color filter CF1, the second color filter CF2, and the third color filter CF3. Each of the plurality of lenses LNS may be a structure for increasing a ratio of light directed to a front surface of the display device 10A. Each of the plurality of lenses LNS may have a cross-sectional shape convex in an upward direction.

The filling layer FIL may be disposed on the plurality of lenses LNS. The filling layer FIL may have a predetermined refractive index so that light travels in the third direction DR3 at an interface between the plurality of lenses LNS and the filling layer FIL. In addition, the filling layer FIL may be a planarizing layer. The filling layer FIL may be an organic film made of an acrylic resin, an epoxy resin, a phenolic resin, a polyamide resin, a polyimide resin, or the like.

The cover layer CVL may be disposed on the filling layer FIL. The cover layer CVL may be a glass substrate or a polymer resin such as a resin. When the cover layer CVL is the glass substrate, the cover layer CVL may be attached onto the filling layer FIL. In this case, the filling layer FIL may serve to adhere the cover layer CVL. When the cover layer CVL is the glass substrate, the cover layer CVL may serve as an encapsulation substrate. When the cover layer CVL is the polymer resin such as the resin, the cover layer CVL may be directly applied onto the filling layer FIL.

The polarizing plate may be disposed on one surface of the cover layer CVL. The polarizing plate may be a structure for preventing deterioration in visibility due to external light reflection. The polarizing plate may include a linear polarizing plate and a phase retardation film. For example, the phase retardation film may be a λ/4 plate (quarter-wave plate), but an exemplary embodiment of the present disclosure is not limited thereto. However, when visibility due to external light reflection is sufficiently improved by the first to third color filters CF1, CF2, and CF3, the polarizing plate may be omitted.

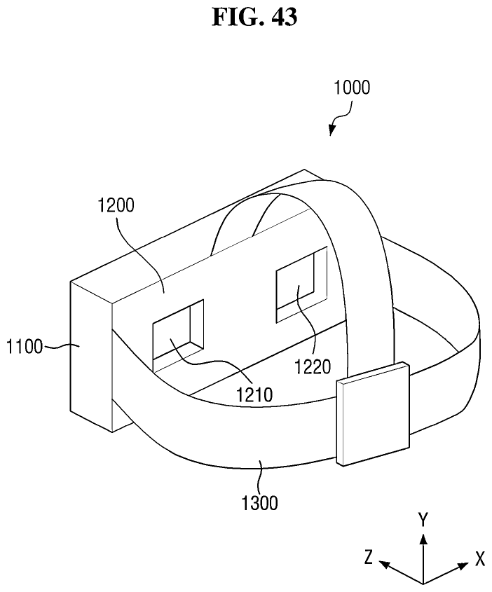

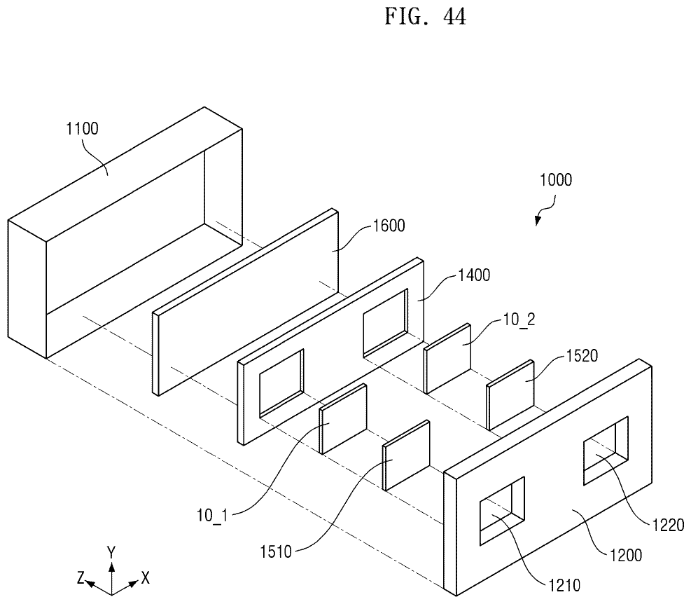

FIG. 43 is a perspective view illustrating a head mounted display device 1000 according to an exemplary embodiment. FIG. 44 is an exploded perspective view illustrating an example of the head mounted display device 1000 of FIG. 43.

Referring to FIGS. 43 and 44, the head mounted display device 1000 as an optical device according to an exemplary embodiment includes a first display device 10_1, a second display device 10_2, a display device housing 1100, a housing part cover 1200, optical path changing members 1210, 1220, 1510, and 1520, a head mounted band 1300, a middle frame 1400, a control circuit board 1600, and a connector.

The optical path changing member may include a first eyepiece 1210, a second eyepiece 1220, a first optical member 1510, and a second optical member 1520.

The first display device 10_1 provides an image to a user's left eye, and the second display device 10_2 provides an image to a user's right eye. Each of the first display device 10_1 and the second display device 10_2 is substantially the same as the display device 10A described with reference to FIGS. 37 to 42, and a description of the first display device 10_1 and the second display device 10_2 is thus omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and be disposed between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source input from the outside into digital video data DATA, and transmit the digital video data DATA to the first display device 10_1 and the second display device 10_2 through the connector.

The control circuit board 1600 may transmit digital video data DATA corresponding to a left eye image optimized for the user's left eye to the first display device 10_1 and transmit digital video data DATA corresponding to a right eye image optimized for the user's right eye to the second display device 10_2. Alternatively, the control circuit board 1600 may transmit the same digital video data DATA to the first display device 10_1 and the second display device 10_2.

The display device housing 1100 serves to house the first display device 10_1, the second display device 102, the middle frame 1400, the first optical member 1510, the second optical member 1520, the control circuit board 1600, and the connector. The housing cover 1200 is disposed to cover opened one surface of the display device housing 1100. The housing cover 1200 may include the first eyepiece 1210 on which the user's left eye is disposed and the second eyepiece 1220 on which the user's right eye is disposed. It has been illustrated in FIGS. 43 and 44 that the first eyepiece 1210 and the second eyepiece 1220 are separately disposed, but an exemplary embodiment of the present disclosure is not limited thereto. The first eyepiece 1210 and the second eyepiece 1220 may be merged as one eyepiece.

The first eyepiece 1210 may be aligned with the first display device 10_1 and the first optical member 1510, and the second eyepiece 1220 may be aligned with the second display device 10_2 and the second optical member 1520. Accordingly, a user may view an image of the first display device 10_1 magnified as a virtual image by the first optical member 1510 through the first eyepiece 1210 and view an image of the second display device 10_2 magnified as a virtual image by the second optical member 1520 through the second eyepiece 1220.

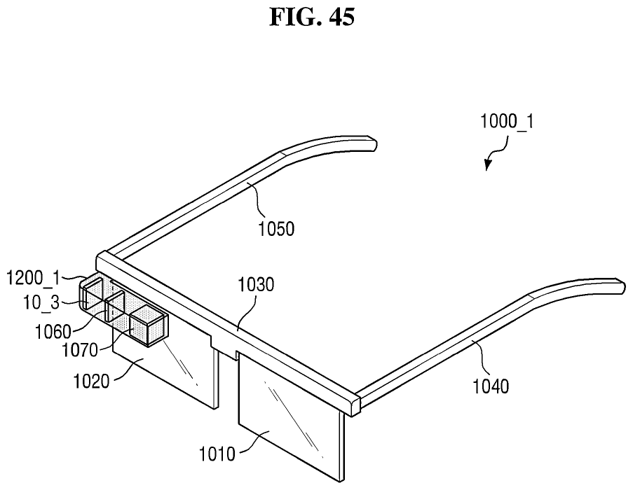

The head mounted band 1300 serves to fix the display device housing 1100 to a user's head so that the first eyepiece 1210 and the second eyepiece 1220 of the housing cover 1200 may be maintained in a state in which they are disposed on the user's left eye and right eye, respectively. When the display device housing 1200 is implemented to have a light weight and a small size, the head mounted display device 1000 may include an eyeglass frame as illustrated in FIG. 45 instead of the head mounted band 1300.

In addition, the head mounted display device 1000 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi) module, or a Bluetooth module.

FIG. 45 is a perspective view illustrating a head mounted display device 1000_1 according to an exemplary embodiment.

Referring to FIG. 45, the head mounted display device 1000_1 as an optical device according to an exemplary embodiment may be a glasses-type display device in which a display device housing 12001 is implemented to have a light weight and a small size. The head mounted display device 1000_1 according to an exemplary embodiment may include a display device 10-3, a left eye lens 1010, a right eye lens 1020, a support frame 1030, glasses frame legs 1040 and 1050, an optical member 1060, an optical path changing member 1070, and the display device housing 12001.

The display device housing 1200_1 may include the display device 103, the optical member 1060, and the optical path changing member 1070. An image displayed on the display device 103 may be magnified by the optical member 1060, changed in an optical path by the optical path changing member 1070, and provided to a user's right eye through the right eye lens 1020. For this reason, a user may view an augmented reality image in which a virtual image displayed on the display device 10_3 through his/her right eye and a real image seen through the right eye lens 1020 are combined with each other.

It has been illustrated in FIG. 45 that the display device housing 12001 is disposed at a right end of the support frame 1030, but an exemplary embodiment of the present disclosure is not limited thereto. For example, the display device housing 12001 may be disposed at a left end of the support frame 1030, and in this case, an image of the display device 10_3 may be provided to a user's left eye. Alternatively, the display device housings 1200_1 may be disposed at both the left and right ends of the support frame 1030, and in this case, the user may view an image displayed on the display device 10_3 through both his/her left and right eyes.

It will be able to be understood by one of ordinary skill in the art to which the present disclosure belongs that the present disclosure may be implemented in other specific forms without changing the technical spirit or essential features of the present disclosure. Therefore, it is to be understood that the exemplary embodiments described above are illustrative rather than being restrictive in all aspects. It is to be understood that the scope of the present disclosure is defined by the claims rather than the detailed description described above and all modifications and alterations derived from the claims and their equivalents fall within the scope of the present disclosure.

What is claimed is:

1. A display device comprising:
a substrate;
a bank disposed on the substrate and defining a plurality of emission areas;
a plurality of pixel electrodes disposed in the plurality of emission areas; and
at least one stepped electrode disposed between a pixel electrode of at least one emission area and the substrate,
wherein in the respective emission areas, the numbers of stepped electrodes between the respective pixel electrodes and the substrate are different from each other.

2. The display device of claim 1, wherein the numbers of stepped electrodes are the numbers of stepped electrodes stacked on different layers with an insulating film interposed therebetween in the respective emission areas.

3. The display device of claim 1, wherein the plurality of emission areas provide light of different colors.

4. The display device of claim 1, further comprising a power line connected to the at least one stepped electrode.

5. The display device of claim 1, wherein the at least one stepped electrode is a floating electrode.

6. The display device of claim 1, further comprising a pixel connection electrode connected to the pixel electrode of the at least one emission area.

7. The display device of claim 6, wherein the at least one stepped electrode is connected to the pixel connection electrode.

8. The display device of claim 1, further comprising a plurality of color filters disposed to correspond to the plurality of emission areas and providing light of different colors.

9. The display device of claim 1, wherein each of the plurality of pixel electrodes includes:
a reflective electrode disposed on the substrate; and
a light-transmitting electrode disposed on the reflective electrode and connected to the reflective electrode through a contact hole of an insulating film.

10. The display device of claim 9, wherein the at least one stepped electrode is disposed between the reflective electrode of the at least one emission area and the substrate.

11. The display device of claim 10, wherein in the respective emission areas, the numbers of stepped electrodes between the respective reflective electrodes and the substrate are different from each other.

12. The display device of claim 9, wherein in the respective emission areas, thicknesses of the respective light-transmitting electrodes are different from each other.

13. The display device of claim 9, further comprising:
a common electrode disposed on a plurality of reflective electrodes of the plurality of pixel electrodes; and
a light providing layer disposed between a plurality of light-transmitting electrodes of the plurality of pixel electrodes and the common electrode.

14. The display device of claim 13, wherein in the plurality of emission areas, distances between the plurality of reflective electrodes and the common electrode are different from each other.

15. The display device of claim 9, wherein a plurality of stepped electrodes include:
a first stepped electrode disposed between the substrate and the reflective electrode;
a second stepped electrode disposed between the first stepped electrode and the reflective electrode.

16. The display device of claim 15, further comprising:
a first pixel connection electrode disposed on a same layer as the first stepped electrode, on the substrate; and
a second pixel connection electrode disposed on the first pixel connection electrode so as to be disposed on a same layer as the second stepped electrode and connected to the first pixel connection electrode and the reflective electrode through contact holes of an insulating film.

17. The display device of claim 16, wherein the first stepped electrode is connected to the first pixel connection electrode.

18. The display device of claim 17, wherein the first stepped electrode is integral with the first pixel connection electrode.

19. The display device of claim 16, wherein the second stepped electrode is connected to the second pixel connection electrode.

20. The display device of claim 19, wherein the second stepped electrode is integral with the second pixel connection electrode.

21. The display device of claim 16, wherein the second stepped electrode is connected to the first stepped electrode through a contact hole of an insulating film.

22. The display device of claim 16, wherein the first stepped electrode is connected to another first stepped electrode disposed in another emission area.

23. A display device comprising:
a substrate;
a bank disposed on the substrate and defining a plurality of emission areas;
a plurality of pixel electrodes disposed in the plurality of emission areas; and
at least one stepped electrode overlapping a pixel electrode of at least one emission area,
wherein the numbers of stepped electrodes in the respective emission areas are different from each other.

24. The display device of claim 23, wherein the numbers of stepped electrodes are the numbers of stepped electrodes stacked on different layers with an insulating film interposed therebetween in the respective emission areas.

25. The display device of claim 23, wherein the plurality of emission areas provide light of different colors.

26. The display device of claim 23, further comprising a power line connected to the at least one stepped electrode.

27. The display device of claim 23, wherein the at least one stepped electrode is a floating electrode.

28. The display device of claim 23, further comprising a pixel connection electrode connected to the pixel electrode of the at least one emission area.

29. The display device of claim 28, wherein the at least one stepped electrode is connected to the pixel connection electrode.

30. A manufacturing method of a display device, comprising:
preparing a substrate;
forming stepped electrodes in different numbers in a plurality of emission areas on the substrate;
forming a first insulating film on the stepped electrodes; and
forming a plurality of pixel electrodes on the first insulating film so as to overlap at least one of the stepped electrodes.

31. The manufacturing method of claim 30, wherein the numbers of stepped electrodes are the numbers of stepped electrodes stacked on different layers with an insulating film interposed therebetween in the respective emission areas.

32. The manufacturing method of claim 30, wherein the plurality of emission areas provide light of different colors.

33. The manufacturing method of claim 30, wherein the forming of the plurality of pixel electrodes includes:
forming a plurality of reflective electrodes on the first insulating film so as to overlap at least one of the stepped electrodes;
forming a second insulating film on the plurality of reflective electrodes;
forming a plurality of contact holes in the second insulating film;
forming a plurality of light-transmitting material layers on the second insulating film so as to overlap the plurality of reflective electrodes and be respectively connected to the plurality of reflective electrodes;
planarizing the light-transmitting material layers; and
forming a plurality of light-transmitting electrodes respectively connected to the plurality of reflective electrodes by patterning the light-transmitting material layers.

34. The manufacturing method of claim 33, wherein the planarizing of the light-transmitting material layers is performed by chemical mechanical polishing.

35. The manufacturing method of claim 30, further comprising forming a plurality of pixel connection electrodes respectively connected to the plurality of pixel electrodes and disposed on different layers from the pixel electrodes with insulating films interposed between the pixel electrodes and the pixel connection electrodes.

36. The manufacturing method of claim 35, wherein a stepped electrode and a pixel connection electrode disposed on a same layer among the stepped electrodes and the plurality of pixel connection electrodes are connected to each other.

37. An optical device comprising:
a display device; and
an optical path changing member disposed on the display device,
wherein the display device includes:
a substrate;
a bank disposed on the substrate and defining a plurality of emission areas;
a plurality of pixel electrodes disposed in the plurality of emission areas; and
at least one stepped electrode disposed between a pixel electrode of at least one emission area and the substrate, and
in the respective emission areas, the numbers of stepped electrodes between the respective pixel electrodes and the substrate are different from each other.
